(19) United States
(12) Patent Application Publication
(10) Pub. No.: US 2025/0087600 A1
(43) Pub. Date: Mar. 13, 2025

(54) SEMICONDUCTOR BONDED STRUCTURE AND FABRICATING METHOD THEREOF

(71) Applicant: MACRONIX International Co., Ltd., Hsinchu (TW)

(72) Inventors: Cheng-Hsien Lu, Taoyuan City (TW); Ming-Hsiu Lee, Hsinchu (TW); Dai-Ying Lee, Hsinchu County (TW)

(73) Assignee: MACRONIX International Co., Ltd., Hsinchu (TW)

(21) Appl. No.: 18/808,098

(22) Filed: Aug. 19, 2024

Related U.S. Application Data
(60) Provisional application No. 63/538,067, filed on Sep. 12, 2023.

(51) Int. Cl. H01L 23/00; H01L 21/3205; H01L 21/78; H01L 25/18; H10B 80/00

(52) U.S. Cl. CPC H01L 23/562; H01L 21/32051; H01L 21/78; H01L 24/06; H01L 24/08; H01L 24/80; H01L 24/94; H01L 25/18; H01L 2224/06181; H01L 2224/08145; H01L 2224/80895; H01L 2224/80896; H01L 2224/94; H10B 80/00

(57) ABSTRACT

A semiconductor bonded structure including a first semiconductor chip, at least one second semiconductor chip, a stress adjusting structure, and a circuit layer is provided. The at least one second semiconductor chip is disposed on the first semiconductor chip and electrically connected to the first semiconductor chip. The stress adjusting structure is disposed in at least one of the first semiconductor chip and the at least one second semiconductor chip. The circuit layer is disposed on the at least one second semiconductor chip and the circuit layer is electrically connected to the at least one second semiconductor chip. A fabricating method of the semiconductor bonded structure is also provided. The semiconductor bonded structure may be applied to the fabrication of 3D NAND flash memory with high performance and high capacity.

### CROSS-REFERENCE TO RELATED APPLICATION

This application claims the priority benefit of U.S. provisional application Ser. No. 63/538,067, filed on Sep. 12, 2023. The entirety of the above-mentioned patent application is hereby incorporated by reference herein and made a part of this specification.

### BACKGROUND OF THE INVENTION

### Field of the Invention

The disclosure relates to a semiconductor bonded structure and a fabricating method thereof, and more particularly to a semiconductor bonded structure having a stress adjusting structure and a fabricating method thereof.

### Description of Related Art

With the increasing trend of memory capacity, the number of device layers needed to fabricate a memory continues to be increased. Taking the current 3D NAND memory as an example, when the stack of silicon oxide-silicon nitride-silicon oxide (ONO) used to store data is increased, the semiconductor wafers used to fabricate 3D NAND memory begin to show significant warpage. The warpage of semiconductor wafers is very unfavorable to the stacking, alignment, and bonding between semiconductor wafers, so the bonding yield between semiconductor wafers is decreased due to the warpage issue. Therefore, how to reduce the warpage of semiconductor wafers so as to increase the bonding yield between semiconductor wafers is one of the important issues that those skilled in the art desire to improve. In addition, when 3D NAND memory is operated at high frequency, the heat dissipation thereof is also one of the issues that those skilled in the art are concerned with. Therefore, how to improve heat dissipation performance and device performance of 3D NAND memory is also one of the important issues that those skilled in the art want to work on.

### SUMMARY OF THE INVENTION

Embodiments of the disclosure provide a semiconductor bonded structure having a stress adjusting structure and a fabricating method thereof.

An embodiment of the disclosure provides a semiconductor bonded structure including a first semiconductor chip, at least one second semiconductor chip, a stress adjusting structure, and a conductive layer. The at least one second semiconductor chip is disposed on and electrically connected to the first semiconductor chip. The stress adjusting structure is disposed in at least one of the first semiconductor chip and the at least one second semiconductor chip. The conductive layer is disposed on and electrically connected to the at least one second semiconductor chip.

Another embodiment of the disclosure provides a fabricating method of a semiconductor bonded structure, including the following steps. A first semiconductor wafer is provided, wherein the first semiconductor wafer includes a first semiconductor substrate and a first interconnect structure disposed on the first semiconductor substrate. The first interconnect structure of the first semiconductor wafer is patterned to form a first stress adjusting opening along a first scribe line of the first semiconductor wafer. A second semiconductor wafer is provided, wherein the second semiconductor wafer includes a second semiconductor substrate and a second interconnect structure disposed on the second semiconductor substrate. The second interconnect structure of the second semiconductor wafer is patterned to form a second stress adjusting opening along a second scribe line of the second semiconductor wafer. The first interconnect structure and the second interconnect structure are bonded. A conductive layer is formed on the second semiconductor substrate after the first interconnect structure and the second interconnect structure are bonded. The first semiconductor wafer, the second semiconductor wafer, and the conductive layer are cut along the first scribe line and the second scribe line to form a plurality of singulated semiconductor bonded structures, wherein each of the plurality of singulated semiconductor bonded structures has a recess capable of adjusting stress on a sidewall thereof respectively.

Another embodiment of the disclosure provides a fabricating method of a semiconductor bonded structure, including the following steps. A first semiconductor wafer is provided, and the first semiconductor wafer includes a first semiconductor substrate and a first interconnect structure disposed at the first semiconductor substrate. A second semiconductor wafer is provided, and the second semiconductor wafer includes a second semiconductor substrate, a plurality of stress adjusting structures embedded in the second semiconductor substrate, and a second interconnect structure disposed on the second semiconductor substrate and the plurality of stress adjusting structures. The first semiconductor wafer and the second semiconductor wafer are bonded. A conductive layer is formed on the second semiconductor substrate and on the plurality of stress adjusting structures after the first semiconductor wafer and the second semiconductor wafer are bonded. The first semiconductor wafer, the second semiconductor wafer, and the conductive layer are cut to form a plurality of singulated semiconductor bonded structures.

### BRIEF DESCRIPTION OF THE DRAWINGS

FIG. 1, FIG. 2, FIG. 3A, FIG. 4A, FIG. 5A, and FIG. 6A are schematic diagrams

of a fabricating process of a semiconductor bonded structure according to the first embodiment of the disclosure.

FIG. 1, FIG. 2, FIG. 3B, FIG. 4B, FIG. 5B, and FIG. 6B are schematic diagrams of a fabricating process of a semiconductor bonded structure according to the second embodiment of the disclosure.

FIG. 7 is a schematic cross-sectional view of a semiconductor bonded structure according to the third embodiment of the disclosure.

FIG. 8 is a schematic cross-sectional view of a semiconductor bonded structure according to the fourth embodiment of the disclosure.

FIG. 9, FIG. 10, FIG. 11A, FIG. 12A, FIG. 13A, FIG. 14A, and FIG. 15A are schematic diagrams of a fabricating process of a semiconductor bonded structure according to the fifth embodiment of the disclosure.

FIG. 9, FIG. 10, FIG. 11B, FIG. 12B, FIG. 13B, FIG. 14B, and FIG. 15B are schematic diagrams of a fabricating process of a semiconductor bonded structure according to the sixth embodiment of the disclosure.

FIG. 16 is a schematic cross-sectional view of a semiconductor bonded structure according to the seventh embodiment of the disclosure.

FIG. 17 is a schematic cross-sectional view of a semiconductor bonded structure according to the eighth embodiment of the disclosure.

FIG. 18, FIG. 19, FIG. 20A, FIG. 21A, FIG. 22A, FIG. 23A, FIG. 24A, and

FIG. 25A are schematic diagrams of a fabricating process of a semiconductor bonded structure according to the ninth embodiment of the disclosure.

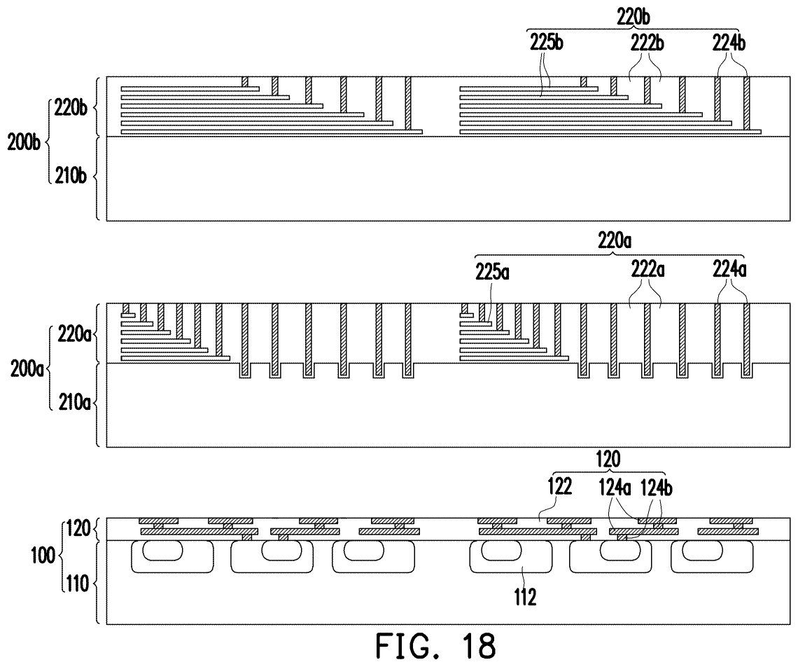

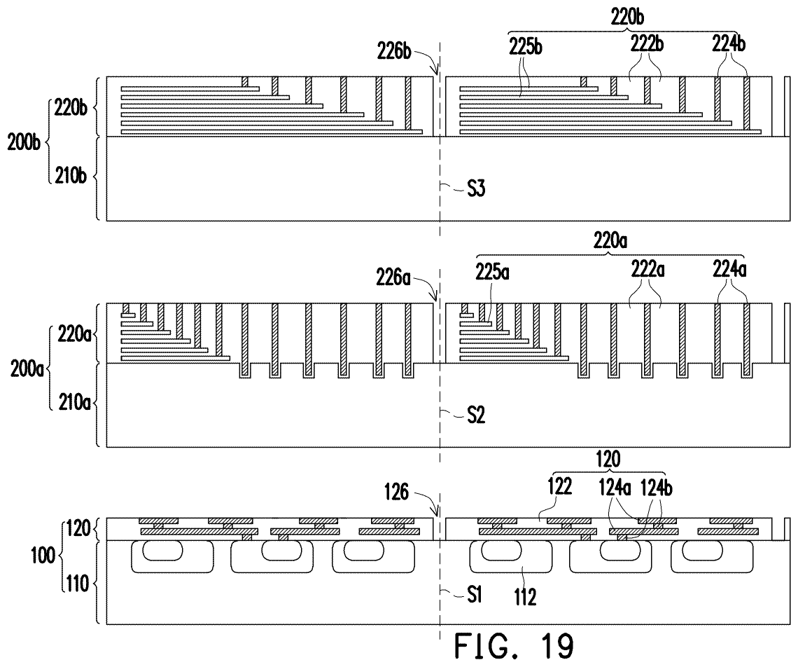

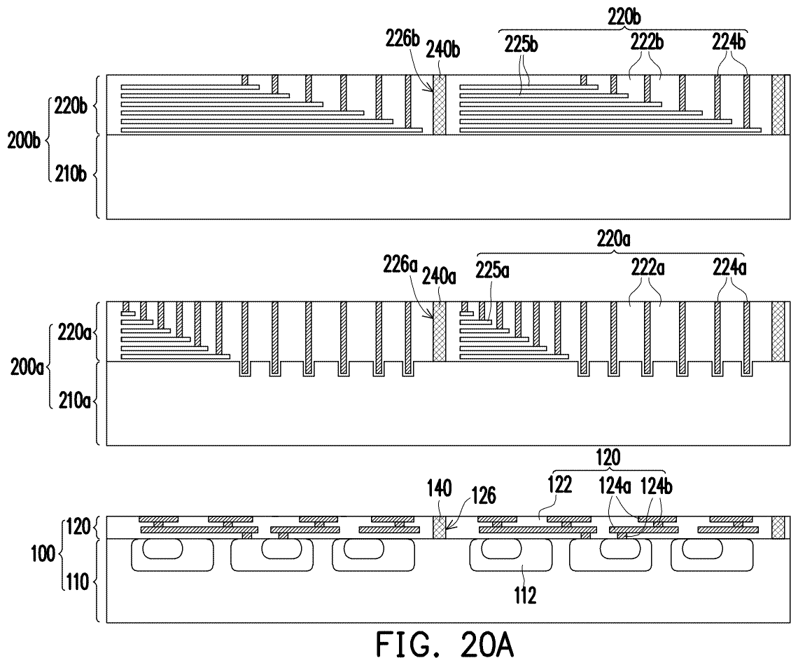

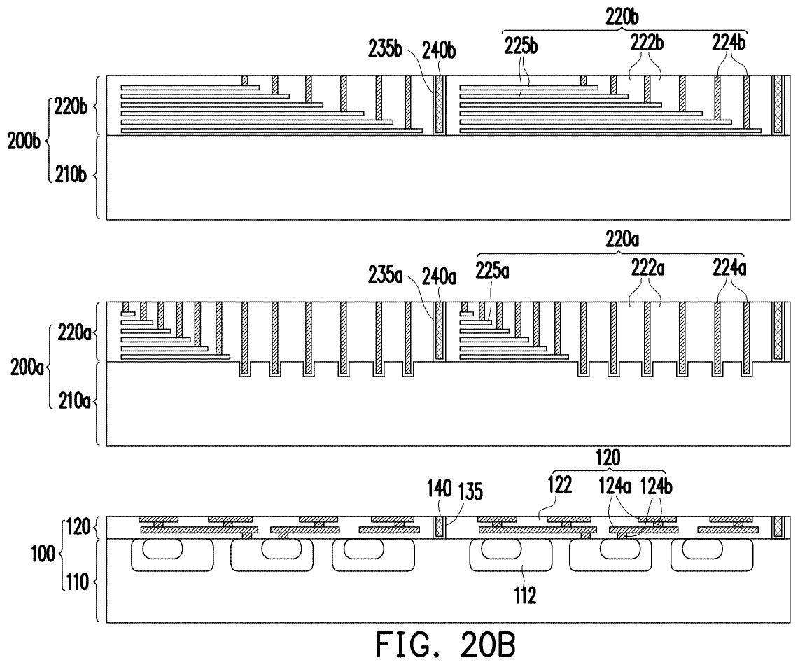

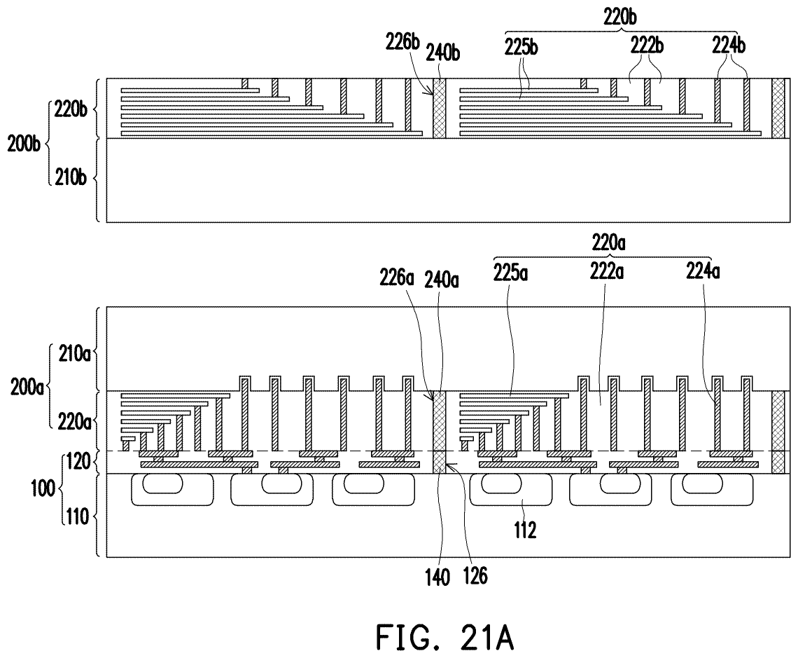

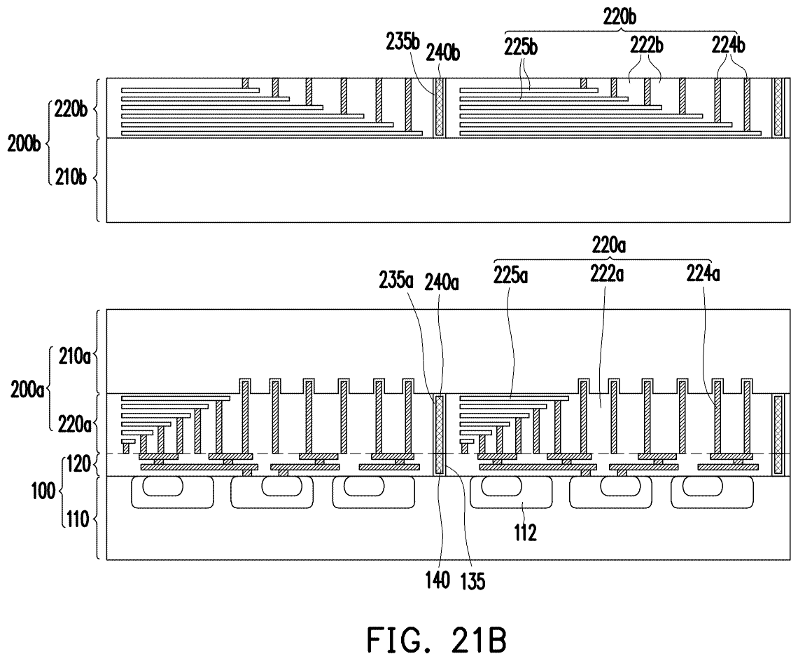

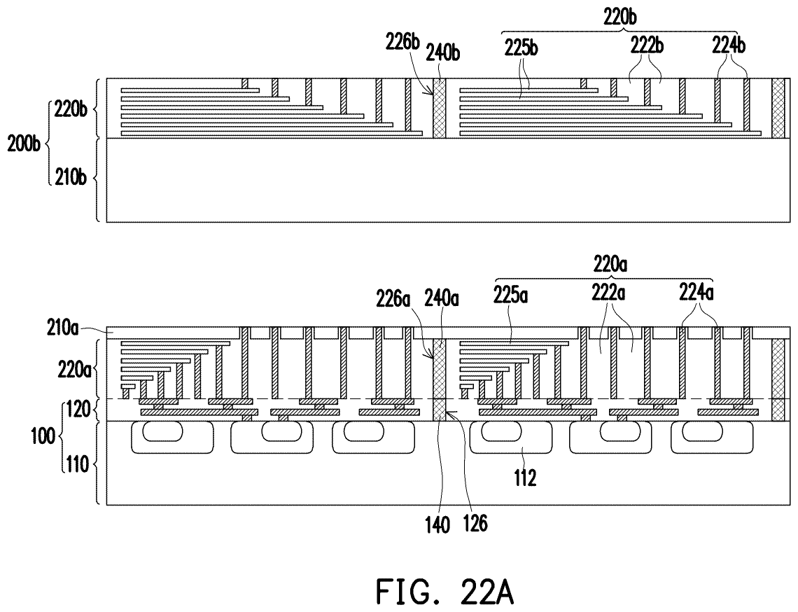

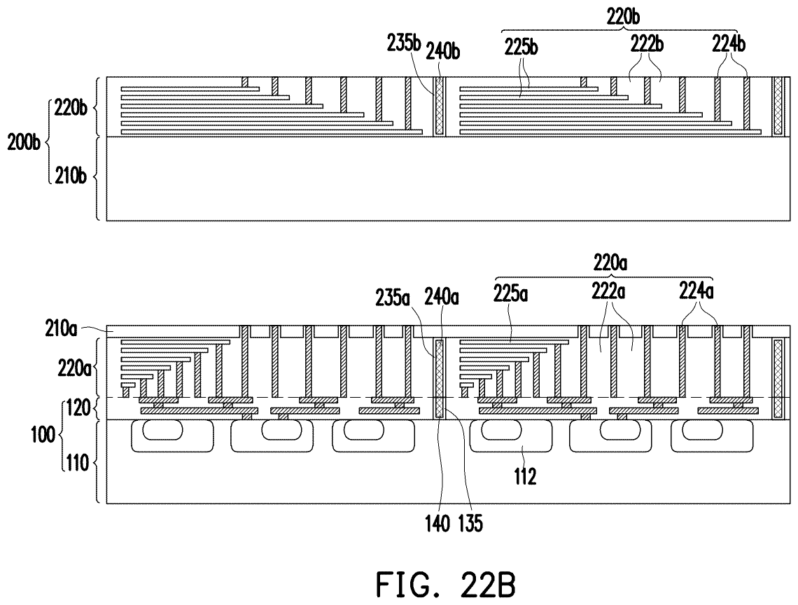

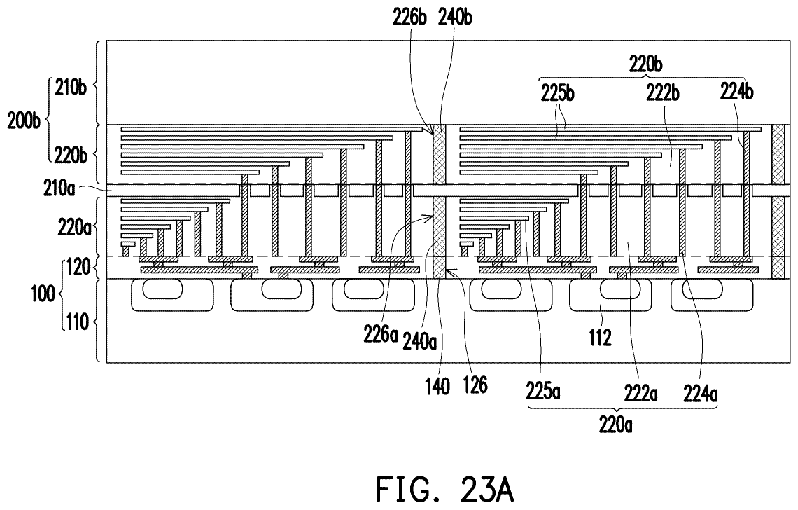

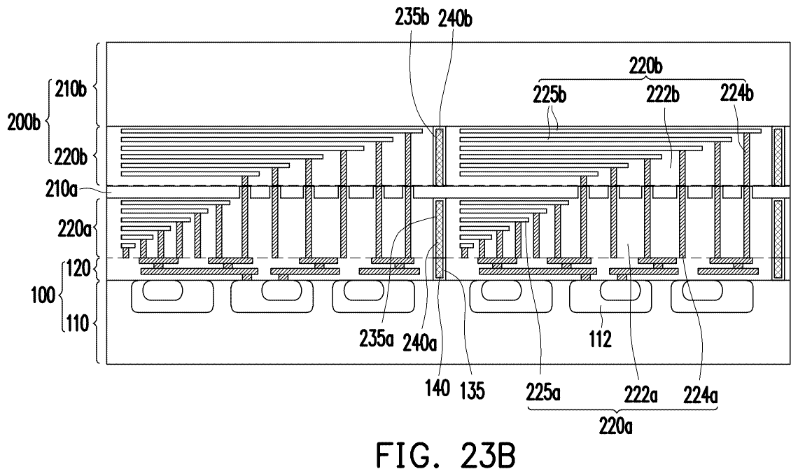

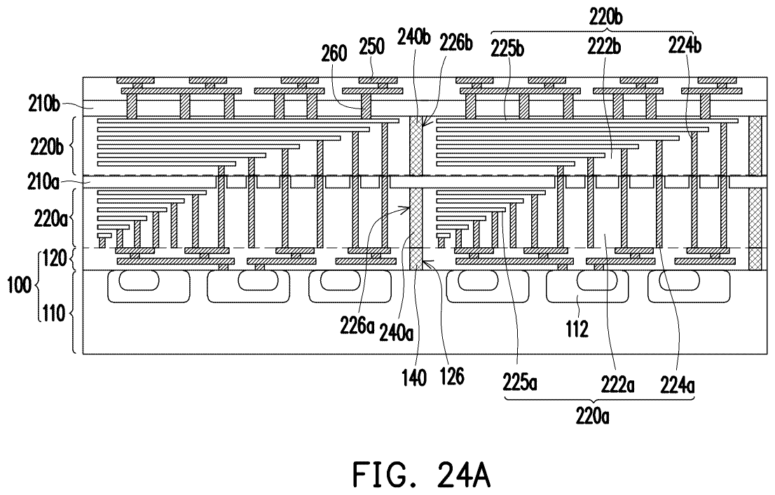

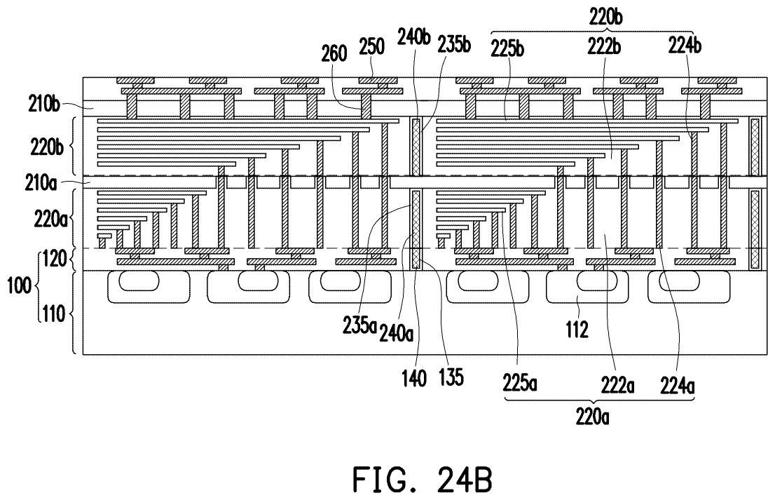

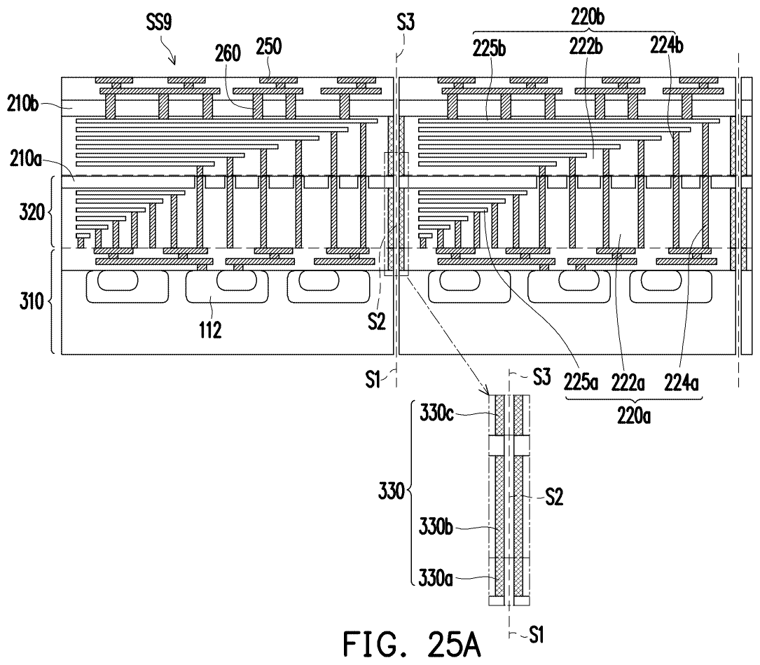

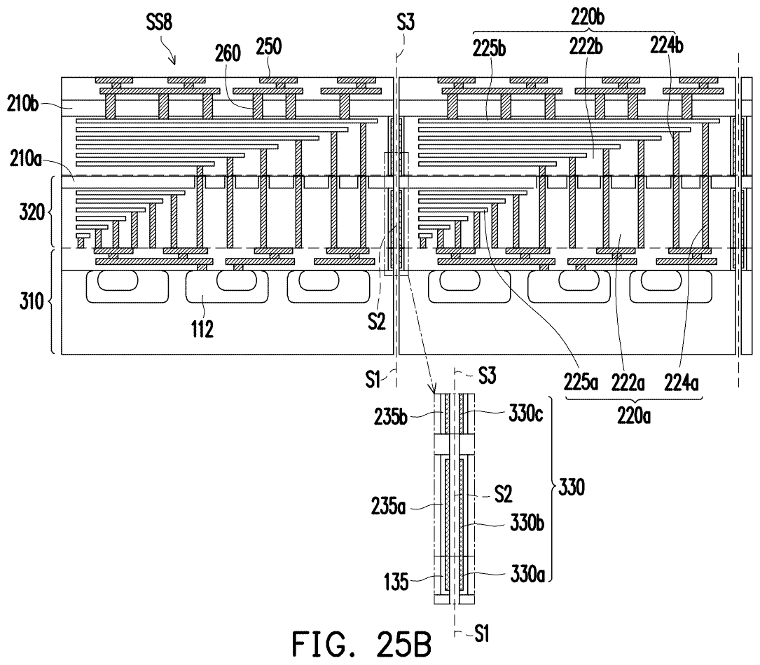

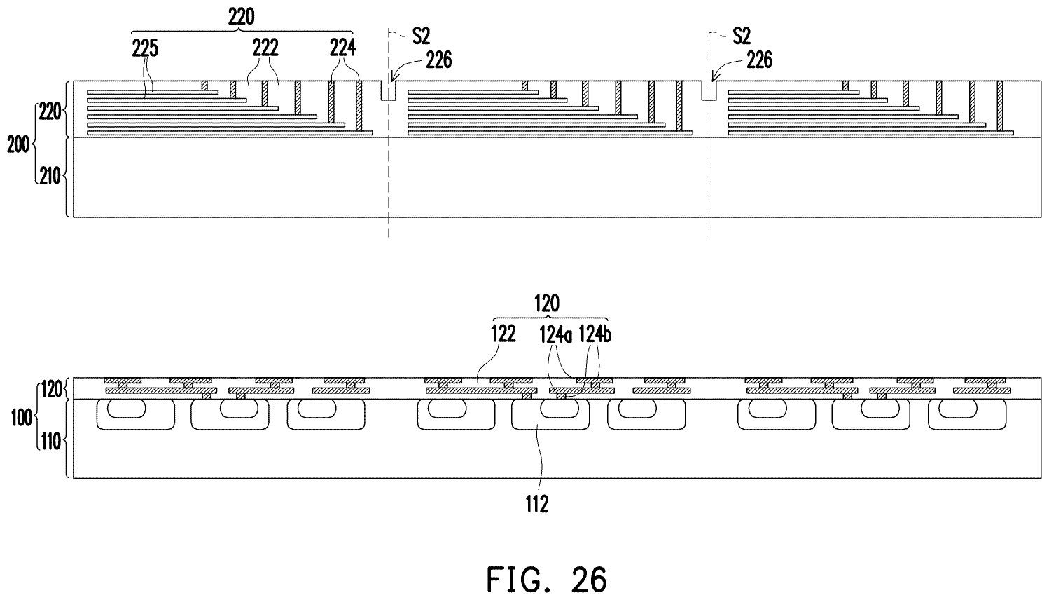

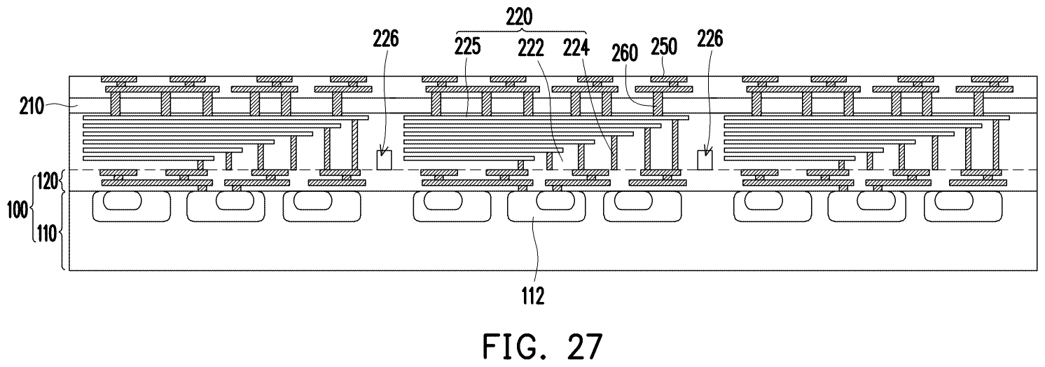

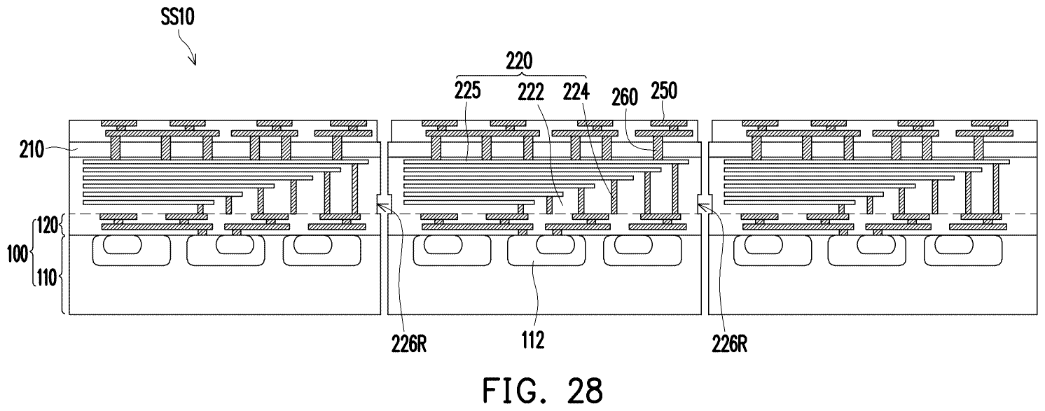

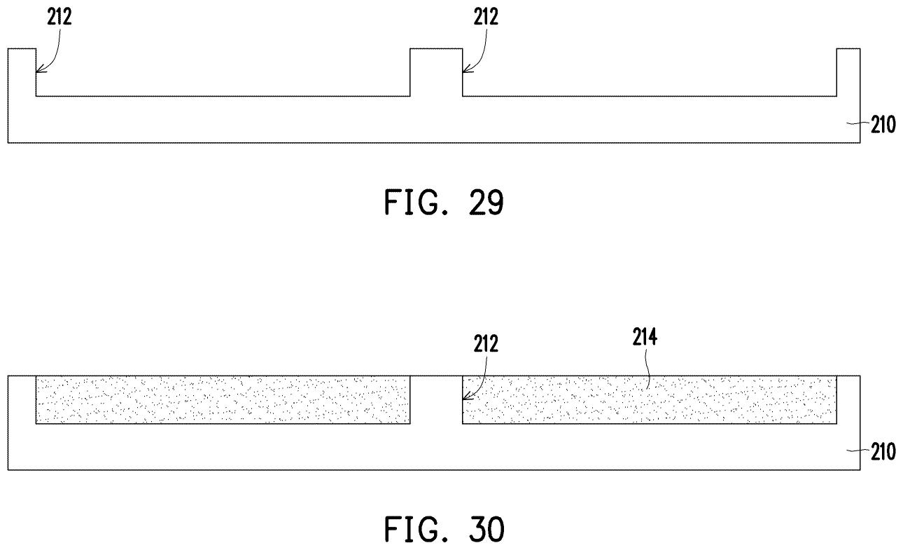

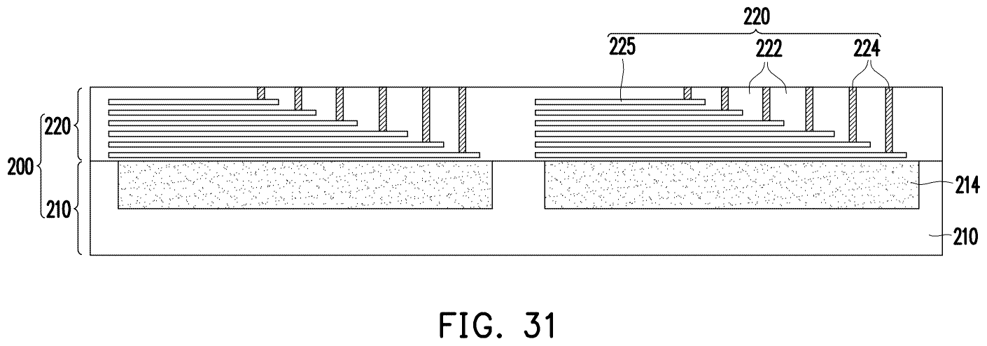

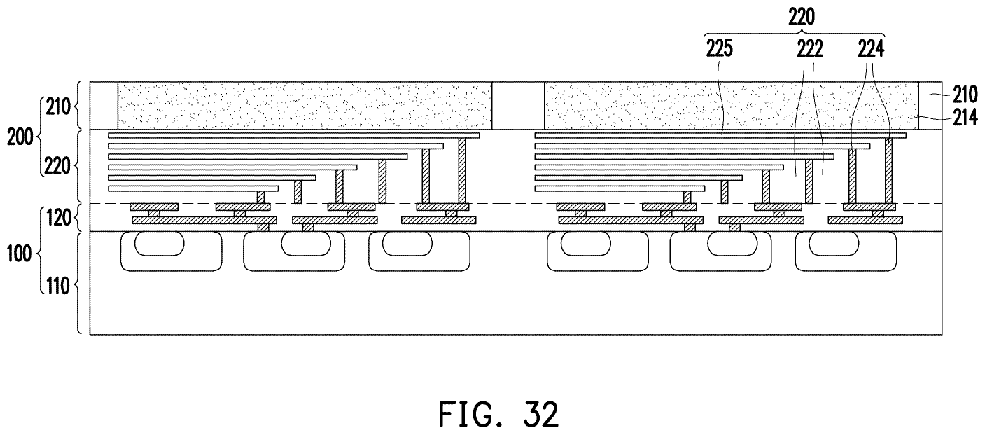

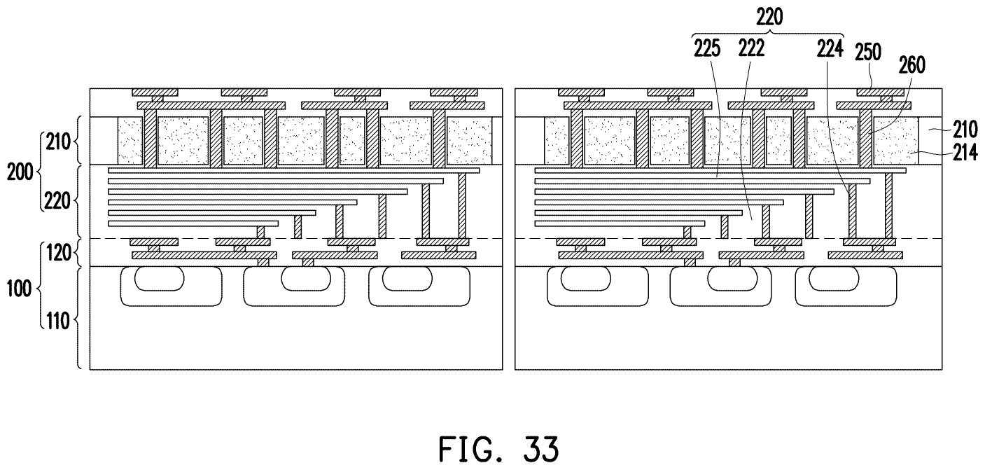

FIG. 18, FIG. 19, FIG. 20B, FIG. 21B, FIG. 22B, FIG. 23B, FIG. 24B, and FIG. 25B are schematic diagrams of a fabricating process of a semiconductor bonded structure according to the tenth embodiment of the disclosure.

FIG. 26 to FIG. 28 are schematic cross-sectional views of a fabricating process of a semiconductor bonded structure according to the eleventh embodiment of the disclosure.

FIG. 29 to FIG. 33 are schematic cross-sectional views of a fabricating process of a semiconductor bonded structure according to the twelfth embodiment of the disclosure.

### DESCRIPTION OF THE EMBODIMENTS

Embodiments are provided hereinafter and described in detail with reference to figures. However, the embodiments provided are not intended to limit the scope of the disclosure. Moreover, the figures are only descriptive and are not drawn to scale. In order to facilitate understanding, the same elements are described with the same reference numerals in the following description. Moreover, terms such as “contain”, “include”, and “have” used in the specification are all open terms, i.e., “contains, but not limited to”.

Moreover, directional terms used in the specification such as “up” and “down” are directions used in the figures and are not used to limit the disclosure. Moreover, the quantities and shapes mentioned in the specification are used to specifically describe the disclosure to facilitate understanding of the content thereof, and not to limit the disclosure.

### First Embodiment

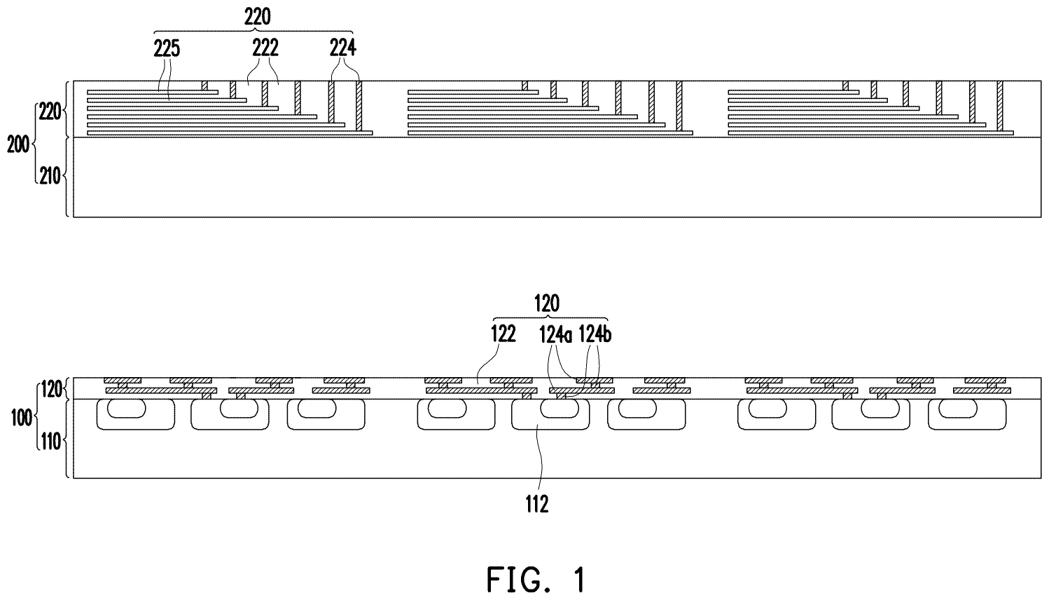

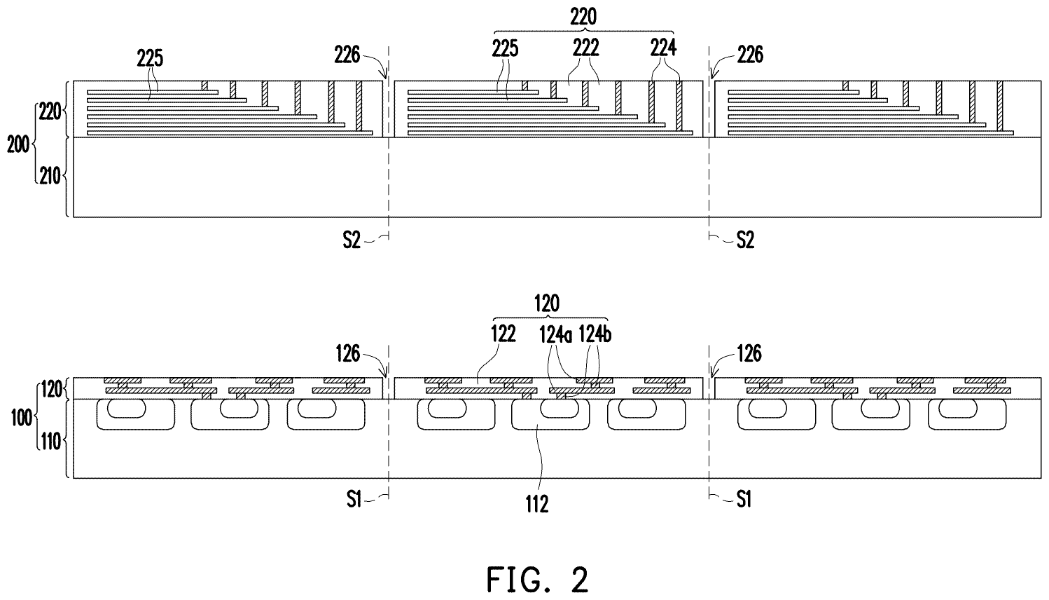

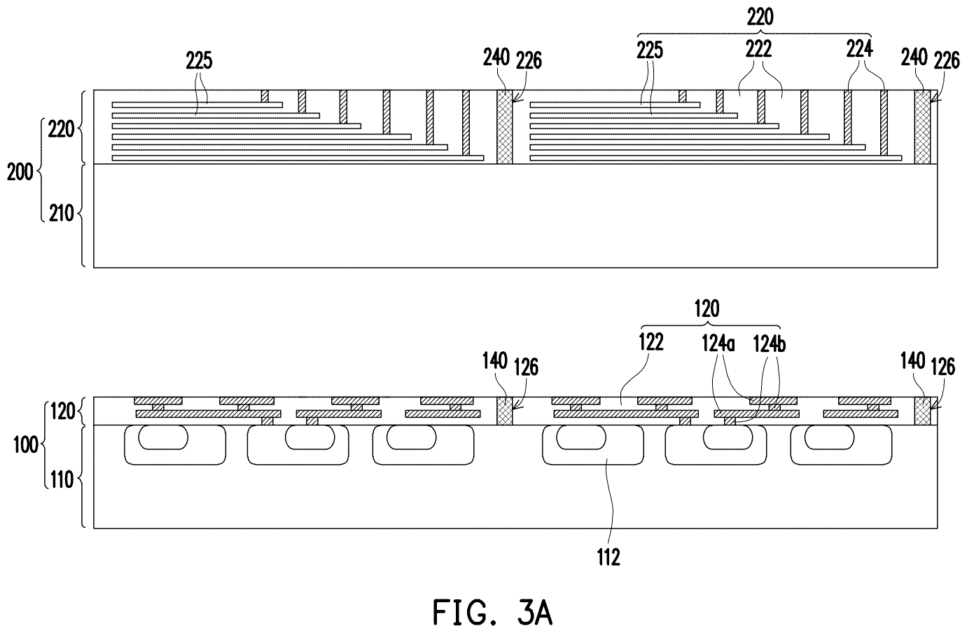

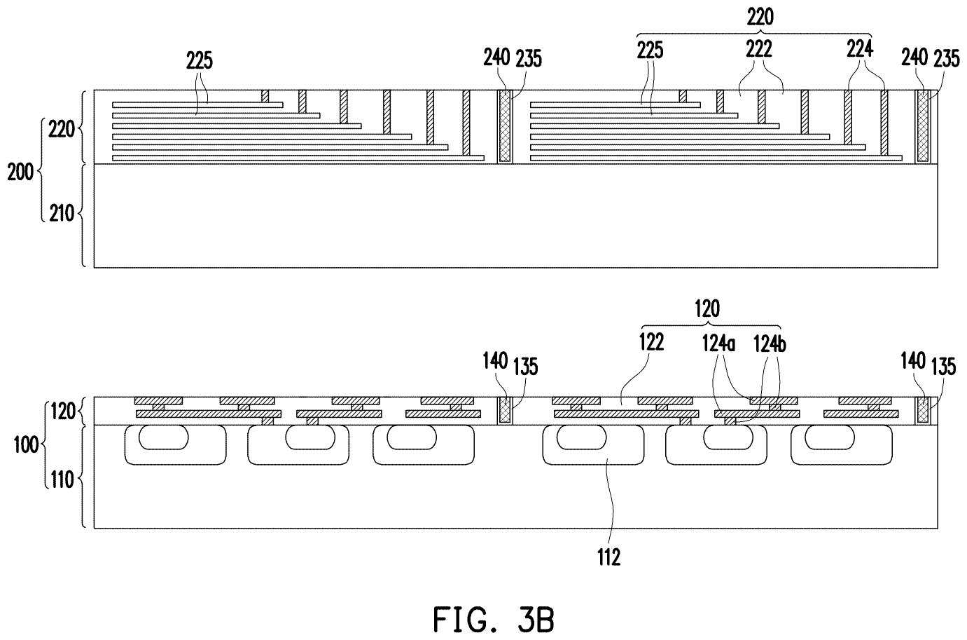

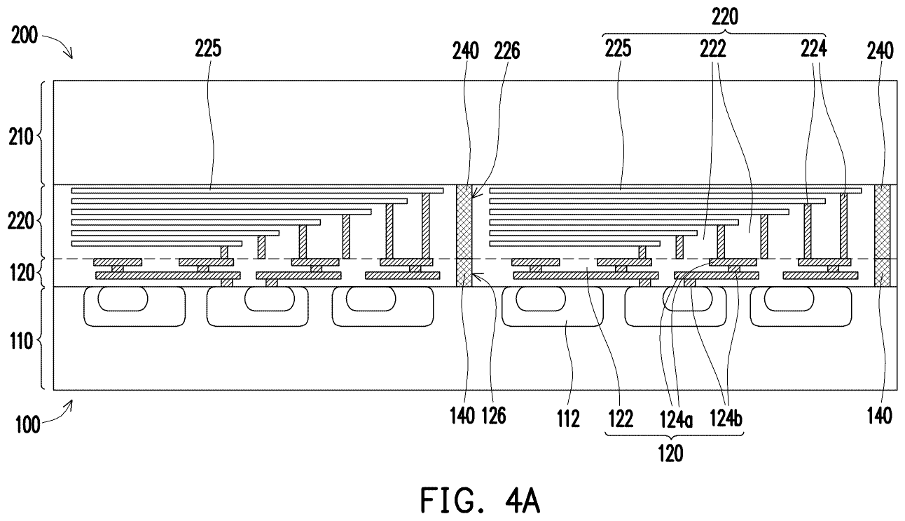

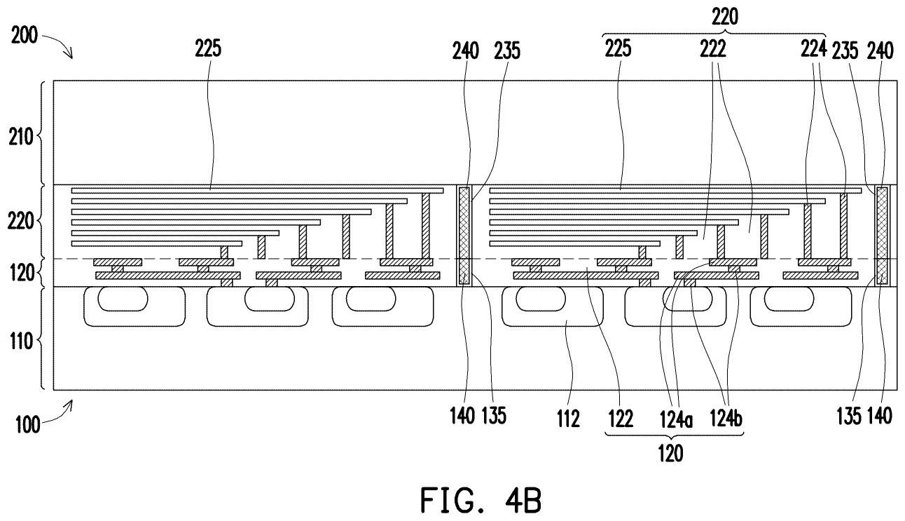

FIG. 1, FIG. 2, FIG. 3A, FIG. 4A, FIG. 5A, and FIG. 6A are schematic diagrams of a fabricating process of a semiconductor bonded structure SS1 according to the first embodiment of the disclosure.

Referring to the lower half of FIG. 1, a first semiconductor wafer 100 is provided. In the present embodiment, the first semiconductor wafer 100 includes a first semiconductor substrate 110 and a first interconnect structure 120, wherein the first interconnect structure 120 is disposed on the first semiconductor substrate 110, and the first interconnect structure 120 is electrically connected to a semiconductor device 112 in the first semiconductor substrate 110. In some embodiments, the first semiconductor substrate 110 in the first semiconductor wafer 100 includes a Group IV semiconductor substrate (such as a silicon substrate), a Group III-V semiconductor substrate, or a substrate of other materials. The semiconductor device 112 in the first semiconductor substrate 110 includes an active device such as a transistor (such as a CMOS field effect transistor) formed in the first semiconductor substrate 110 and/or a passive device such as a resistor, a capacitor, or an inductor. The first interconnect structure 120 includes a plurality of dielectric layers 122 stacked on the first semiconductor substrate 110, a plurality of interconnect wirings 124a embedded in the dielectric layers 122, and a plurality of conductive vias 124b connected between different layers of the interconnect wirings 124a. The semiconductor device 112 in the first semiconductor substrate 110 is fabricated by front end of line (FEOL) processes, and the dielectric layers 122, the interconnect wirings 124a, and the conductive vias 124b in the first interconnect structure 120 are fabricated by back end of line (BEOL) processes.

As shown in the lower half of FIG. 1, the interconnect wirings 124a and the conductive vias 124b are embedded in the dielectric layers 122, wherein the interconnect wirings 124a of different layers are electrically connected to each other via the conductive vias 124b, and the interconnect wirings 124a are electrically connected to the active device 112 in the first semiconductor substrate 110 via the conductive vias 124b. For example, the material of the dielectric layers 122 in the first interconnect structure 120 includes SiO₂, SiON, SiN, SiC, SiCN, a polymer material, or other insulating materials, the material of the interconnect wirings 124a includes polysilicon, copper, gold, silver, cobalt, or other metals, and the material of the conductive vias 124b includes polysilicon, copper, gold, silver, cobalt, or other metals. In addition, the interconnect wirings 124a may be single-layer metal layers or multi-layer metal layers.

Referring to the upper half of FIG. 1, a second semiconductor wafer 200 is provided. In the present embodiment, the second semiconductor wafer 200 includes a second semiconductor substrate 210 and a second interconnect structure 220, wherein the second semiconductor substrate 210 may or may not have a semiconductor device, the second interconnect structure 220 is disposed on the second semiconductor substrate 210. In some embodiments, the second semiconductor substrate 210 in the second semiconductor wafer 200 includes a Group IV semiconductor substrate (such as a silicon substrate), a Group III-V semiconductor substrate, or a substrate of other materials. The second interconnect structure 220 includes a plurality of dielectric layers 222 stacked on the second semiconductor substrate 210, a plurality of memory device layers 225, and a plurality of layers of conductive vias 224 embedded in the dielectric layers 222, wherein the plurality of memory device layers 225 are stacked on the second semiconductor substrate 210, and the plurality of memory device layers 225 are embedded in the plurality of dielectric layers 222. In the present embodiment, the dielectric layers 222 and the conductive vias 224 in the second interconnect structure 220 are fabricated by back end of line (BEOL) processes. For example, the material of the dielectric layers 222 in the second interconnect structure 220 includes SiO₂, SiON, SiN, SiC, SiCN, a polymer material, or other insulating materials, and the material of the conductive vias 224 includes polysilicon, copper, gold, silver, cobalt, or other metals. In some embodiments, each of the memory device layers 225 is electrically connected to the bottom end of at least one of the conductive vias 224 respectively, and the top ends of the conductive vias 224 are exposed on the upper surface of the second interconnect structure 220.

In some embodiments, the memory device layers 225 include a plurality of 3D NAND memory device layers, and the memory device layers 225 may include at least 300 layers of silicon oxide-silicon-tungsten-silicon oxide (OWO) stacks which are formed from silicon oxide-silicon nitride-silicon oxide (ONO) stacks. In other possible embodiments, the memory device layers 225 include a plurality of 3D NAND memory device layers, and the memory device layers 225 may include at least 1000 layers of silicon oxide-silicon-tungsten-silicon oxide (OWO) stacks which are formed from silicon oxide-silicon nitride-silicon oxide (ONO) stacks.

Referring to FIG. 2 and FIG. 3A, in order to relieve the stress of the first semiconductor wafer 100 and/or the second semiconductor wafer 200 so as to reduce the degree of warpage of the first semiconductor wafer 100 and/or the second semiconductor wafer 200, a patterning process (for example, an etching process) may be performed on at least one of the first semiconductor wafer 100 and the second semiconductor wafer 200, and a stress adjusting structure is formed in at least one of the first semiconductor wafer 100 and the second semiconductor wafer 200. In the present embodiment, a patterning process may be first performed on the first semiconductor wafer 100, and then a first stress adjusting structure 140 is formed in the first semiconductor wafer 100, and a patterning process is performed on the second semiconductor wafer 200, and then a second stress adjusting structure 240 is formed in the second semiconductor wafer 200. It should be noted that the invention does not limit the forming sequence of the first stress adjusting structure 140 and the second stress adjusting structure 240.

As shown in FIG. 2, a patterning process is performed on the first interconnect structure 120 of the first semiconductor wafer 100 to form first stress adjusting openings 126 distributed in the first interconnect structure 120 along a first scribe line S1 of the first semiconductor wafer 100. Moreover, a patterning process is performed on the second interconnect structure 220 of the second semiconductor wafer 200 to form second stress adjusting openings 226 distributed in the second interconnect structure 220 along a second scribe line S2 of the second semiconductor wafer 200. The first stress adjusting openings 126 and the second stress adjusting openings 226 may have various cross-sectional shapes, such as semicircular, rectangular, trapezoidal, hexagonal, stepped, etc., and the widths of the first stress adjusting openings 126 and the second stress adjusting openings 226 are between a few micrometers and hundreds of micrometers. In the present embodiment, the height of the first stress adjusting openings 126 is substantially equal to the thickness of the first interconnect structure 120, and the height of the second stress adjusting openings 226 is substantially equal to the thickness of the second interconnect structure 220. Moreover, a partial area of the first semiconductor substrate 110 is exposed by the first stress adjusting openings 126, and a partial area of the second semiconductor substrate 210 is exposed by the second stress adjusting openings 226. After the first stress adjusting openings 126 and the second stress adjusting openings 226 are formed, since the stress of the first semiconductor wafer 100 and the second semiconductor wafer 200 is released by the first stress adjusting openings 126 and the second stress adjusting openings 226, the warping of the first semiconductor wafer 100 and the second semiconductor wafer 200 may be alleviated to a certain extent.

As shown in FIG. 2 and FIG. 3A, a stress adjusting material is filled in the first stress adjusting openings 126 and the second stress adjusting openings 226, so as to respectively form the first stress adjusting structure 140 and the second stress adjusting structure 240 in the first stress adjusting openings 126 and the second stress adjusting openings 226. In the present embodiment, by forming a stress adjusting material on the first interconnect structure 120 and in the first stress adjusting openings 126, then removing the stress adjusting material outside the first stress adjusting openings 126 by a planarization process (for example, a chemical mechanical polishing process, a mechanical grinding process, or a combination of the above processes), the first stress adjusting structure 140 may be formed. Moreover, by forming a stress adjusting material on the second interconnect structure 220 and in the second stress adjusting openings 226, then removing the stress adjusting material outside the second stress adjusting openings 226 by a planarization process (for example, a chemical mechanical polishing process, a mechanical grinding process, or a combination of the above processes), the second stress adjusting structure 240 may be formed. In the present embodiment, the height of the first stress adjusting structure 140 is substantially equal to the thickness of the first interconnect structure 120, and the height of the second stress adjusting structure 240 is substantially equal to the thickness of the second interconnect structure 220. In some other embodiments, the height of the first stress adjusting structure 140 is greater than or small than the thickness of the first interconnect structure 120, and the height of the second stress adjusting structure 240 is greater than or smaller than the thickness of the second interconnect structure 220. For example, when the coefficient of thermal expansion (CTE) of the first stress adjusting structure 140 is greater than the CTE of the dielectric layers 122 of the first interconnect structure 120, the height of the first stress adjusting structure 140 is slightly less than (e.g., several nanometers) the thickness of the first interconnect structure 120. The material of the first stress adjusting structure 140 may be or include metals, certain polymers, or graphene. When the coefficient of thermal expansion (CTE) of the first stress adjusting structure 140 is greater than the CTE of SiO₂ (which is about 0.7-1.4 W/m·K), the first stress adjusting structure 140 may provide favorable heat dissipation performance. When material of the first stress adjusting structure 140 may be or include polymer materials with characteristics of water absorption, the first stress adjusting structure 140 may retain water in the film to prevent degradation of the subsequently formed bonding interface. On the contrary, when the CTE of the first stress adjusting structure 140 is less than the CTE of the dielectric layers 122 of the first interconnect structure 120, the height of the first stress adjusting structure 140 substantially equals to or is slightly greater than (e.g., several nanometers) the thickness of the first interconnect structure 120. Similarly, when the coefficient of thermal expansion (CTE) of the second stress adjusting structure 240 is greater than the CTE of the dielectric layers 222 of the second interconnect structure 220, the height of the second stress adjusting structure 240 is slightly less than (e.g., several nanometers) the thickness of the second interconnect structure 220. The material of the second stress adjusting structure 240 may be or include metals, certain polymers, or graphene. When the coefficient of thermal expansion (CTE) of the second stress adjusting structure 240 is greater than the CTE of SiO₂ (which is about 0.7-1.4 W/m·K), the second stress adjusting structure 240 may provide favorable heat dissipation performance. When material of the second stress adjusting structure 240 may be or include polymer materials with characteristics of water absorption, the second stress adjusting structure 240 may retain water in the film to prevent degradation of the subsequently formed bonding interface. On the contrary, when the CTE of the second stress adjusting structure 240 is less than the CTE of the dielectric layers 222 of the second interconnect structure 220, the height of the second stress adjusting structure 240 substantially equals to or is slightly greater than (e.g., several nanometers) the thickness of the second interconnect structure 220.

In some embodiments, the material of the first stress adjusting structure 140 and the second stress adjusting structure 240 includes a polymer material, such as polyimide (PI), epoxy resin, benzocyclobutene (BCB), SU-8, or other suitable stress buffering materials. The material of the first stress adjusting structure 140 may be the same as or different from the material of the second stress adjusting structure 240. In other embodiments, the material of the first stress adjusting structure 140 and the second stress adjusting structure 240 includes an inorganic material, such as carbon, silicon, SiCN, silicon carbide (SiC), silicon oxide (SiOₓ), borophosphosilicate glass (BPSG), phosphosilicate glass (PSG), borosilicate glass (BSG), inorganic 2D material, etc. In other possible embodiments, the material of the first stress adjusting structure 140 and the second stress adjusting structure 240 includes a metal material, such as tungsten (W), copper (Cu), aluminum (Al), silver (Ag), gold (Au), metal 2D material, etc.

Based on the above, in addition to the function of stress adjustment, the first stress adjusting structure 140 and the second stress adjusting structure 240 may also have good heat dissipation properties, water absorption properties, or other functions.

Referring to FIG. 4A, the second semiconductor wafer 200 is turned over, and the second semiconductor wafer 200 is aligned with the first semiconductor wafer 100. After the second semiconductor wafer 200 and the first semiconductor wafer 100 are aligned, the second stress adjusting structure 240 in the second interconnect structure 220 is aligned with the first stress adjusting structure 140 in the first interconnect structure 120, and the conductive vias 224 in the second interconnect structure 220 are aligned with the interconnect wirings 124a in the first interconnect structure 120. After the alignment of the second semiconductor wafer 200 and the first semiconductor wafer 100 is completed, a bonding process between the second semiconductor wafer 200 and the first semiconductor wafer 100 is performed, such as a hybrid bonding process, a micro-bump bonding process, etc., so that the patterned first interconnect structure 120 and the patterned second interconnect structure 220 are bonded to each other. In some embodiments, while the first interconnect structure 120 and the second interconnect structure 220 are bonded to each other, the second stress adjusting structure 240 is well-bonded to the first stress adjusting structure 140, wherein the first stress adjusting structure 140 and the second stress adjusting structure 240 may serve as a sealing structure to prevent water from entering the bonding interface and enhance the bonding strength, thereby improving overall bonding quality. The above-mentioned hybrid bonding process may include a pre-bonding process followed by an annealing process, wherein the pre-bonding process may be performed under room temperature without applying bonding force, and the annealing process may be performed under 350 Celsius degrees for about 30 minutes to about 60 minutes. The above-mentioned micro-bump bonding process may be performed under 260 Celsius degrees for about 5 minutes, and the above-mentioned micro-bump bonding process may be performed under 0.4 MPa bonding pressure. Since the first stress adjusting structure 140 and the second stress adjusting structure 240 may reduce the warping of the second semiconductor wafer 200 and the first semiconductor wafer 100, the bonding yield between the second semiconductor wafer 200 and the first semiconductor wafer 100 may be improved.

Please refer to FIG. 4A and FIG. 5A, after the bonding process between the second semiconductor wafer 200 and the first semiconductor wafer 100 is performed, a conductive layer 250 (e.g., a redistribution circuit layer) electrically connected to the second semiconductor wafer 200 is formed on the second semiconductor substrate 210. In some embodiments, before the conductive layer 250 is fabricated, the second semiconductor substrate 210 may be thinned first by a mechanical grinding process followed by a chemical mechanical polishing process, and a plurality of conductive through vias 260 electrically connected to the memory device layers 225 are formed in the second semiconductor substrate 210, and then the conductive layer 250 is fabricated. In some embodiments, the conductive through vias 260 may be through silicon vias (TSVs). As shown in FIG. 5A, the conductive layer 250 and the second interconnect structure 220 are respectively located at two opposite sides of the second semiconductor substrate 210, and the conductive layer 250 is electrically connected to the memory device layers 225 via the TSVs 260.

Please refer to FIG. 5A and FIG. 6A, the first semiconductor wafer 100, the second semiconductor wafer 200, the first stress adjusting structure 140, the second stress adjusting structure 240, and the conductive layer 250 are cut along the first scribe line S1 and the second scribe line S2 to form a plurality of singulated semiconductor bonded structures SS1. As shown in FIG. 6A, each of the plurality of singulated semiconductor bonded structures SS1 has a stress adjusting structure 330 on a sidewall thereof, respectively. The first stress adjusting structure 140 and the second stress adjusting structure 240 may have width of about 80 micrometers, the width of the second scribe line S2 may range from about 20 micrometers to about 40 micrometers, and the width of the stress adjusting structure 330 may range from about 20 micrometers to about 30 micrometers. The singulated semiconductor bonded structures SS1 include a first semiconductor chip 310, a second semiconductor chip 320, the stress adjusting structure 330, and the conductive layer 250. The second semiconductor chip 320 is disposed on the first semiconductor chip 310 and electrically connected to the first semiconductor chip 310. The stress adjusting structure 330 is embedded on the sidewalls of the first semiconductor chip 310 and the second semiconductor chip 320. In addition, the conductive layer 250 is disposed on the second semiconductor chip 320, and the conductive layer 250 is electrically connected to the second semiconductor chip 320.

It should be noted that, as shown in FIG. 5A and FIG. 6A, the stress adjusting structure 330 in each of the singulated semiconductor bonded structures SS1 is formed by a portion of the first stress adjusting structure 140 and a portion of the second stress adjusting structure 240. As shown in FIG. 5A and FIG. 6A, the stress adjusting structure 330 includes a first stress adjusting region 330a and a second stress adjusting region 330b, wherein the first stress adjusting region 330a is the remaining portion of the first stress adjusting structure 140 after cutting, and the second stress adjusting region 330b is the remaining portion of the second stress adjusting structure 240 after cutting. Moreover, the first stress adjusting region 330a is disposed on the sidewall of the first interconnect structure 120, and the second stress adjusting region 330b is disposed on the sidewall of the second interconnect structure 220. In an embodiment in which the first stress adjusting structure 140 and the second stress adjusting structure 240 adopt the same material for fabrication, there is no significant interface between the first stress adjusting region 330a and the second stress adjusting region 330b. In an embodiment in which the first stress adjusting structure 140 and the second stress adjusting structure 240 adopt different materials for fabrication, there is a heterogeneous interface between the first stress adjusting region 330a and the second stress adjusting region 330b.

In some embodiments, the first stress adjusting region 330a in the stress adjusting structure 330 includes an annular wall structure, wherein the annular wall structure is distributed on the sidewall of the first interconnect structure 120 of the first semiconductor chip 310 and surrounds the first semiconductor chip 310. In some other embodiments, the first stress adjusting region 330a in the stress adjusting structure 330 includes a plurality of columnar structures, wherein the plurality of columnar structures are distributed on the sidewall of the first interconnect structure 120 of the first semiconductor chip 310, the plurality of columnar structures are disposed around the first semiconductor chip 310, and the plurality of columnar structures are separated from each other. For example, the columnar structures may have various cross-sectional shapes, such as semicircular, rectangular, trapezoidal, hexagonal, stepped, etc., and the width of the columnar structures is between a few micrometers and hundreds of micrometers. In addition, the arrangement pitch of the columnar structures is between a few micrometers and hundreds of micrometers.

In some embodiments, the second stress adjusting region 330b in the stress adjusting structure 330 includes an annular wall structure, wherein the annular wall structure is distributed on the sidewall of the second interconnect structure 220 of the second semiconductor chip 320 and surrounds the second semiconductor chip 320. In some other embodiments, the second stress adjusting region 330b in the stress adjusting structure 330 includes a plurality of columnar structures, wherein the plurality of columnar structures are distributed on the sidewall of the second interconnect structure 220 of the second semiconductor chip 320, the plurality of columnar structures are disposed around the second semiconductor chip 320, and the plurality of columnar structures are separated from each other.

As shown in FIG. 6A, in the singulated semiconductor bonded structures SS1, the height of the first stress adjusting region 330a is substantially equal to the thickness of the first interconnect structure 120 of the first semiconductor chip 310, and the height of the second stress adjusting region 330b is substantially equal to the thickness of the second interconnect structure 220 of the second semiconductor chip 320. In other words, the height of the stress adjusting structure 330 is substantially equal to the sum of the thicknesses of the first interconnect structure 120 and the second interconnect structure 220. Moreover, the height of the first stress adjusting region 330a is less than the thickness of the first semiconductor chip 310, and the height of the second stress adjusting region 330b is less than the thickness of the second semiconductor chip 320.

### Second Embodiment

FIG. 1, FIG. 2, FIG. 3B, FIG. 4B, FIG. 5B, and FIG. 6B are schematic diagrams of a fabricating process of a semiconductor bonded structure SS2 according to the second embodiment of the disclosure.

The fabricating process shown in FIG. 3B, FIG. 4B, FIG. 5B, and FIG. 6B is similar to the fabricating process shown in FIG. 3A, FIG. 4A, FIG. 5A, and FIG. 6A except that the fabricating process in FIG. 3B, FIG. 4B, FIG. 5B, and FIG. 6B further includes the forming of functional material layers 135 and 235. In other words, the semiconductor bonded structure SS2 in the present embodiment further includes functional material layers 135 and 235 (as shown in FIG. 6B), wherein the first stress adjusting region 330a and the second stress adjusting region 330b are respectively separated from the first interconnect structure 120 of the first semiconductor chip 310 and the second interconnect structure 220 of the second semiconductor chip 320 via the functional material layers 135 and 235. In some embodiments, the first stress adjusting region 330a and the second stress adjusting region 330b have a stress adjusting function, and the material of the functional material layers 135 and 235 may be a heat dissipation material having good heat dissipation properties, a water absorption material having good water absorption properties, or other functional materials.

### Third Embodiment

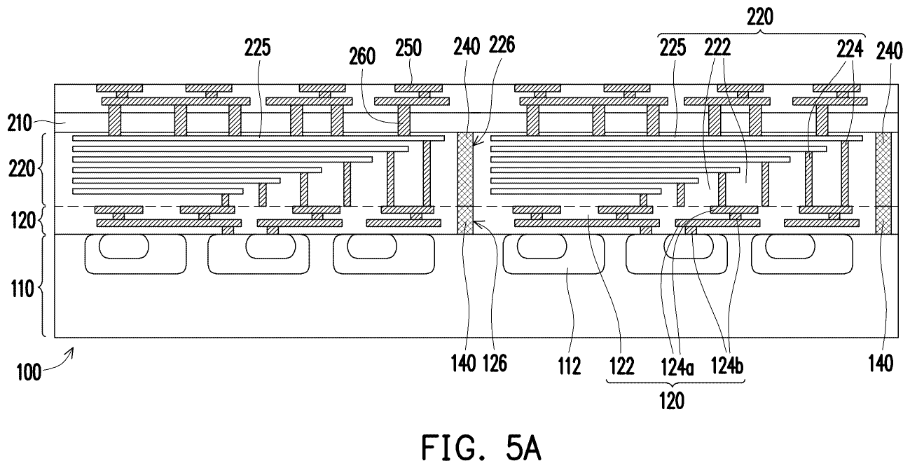

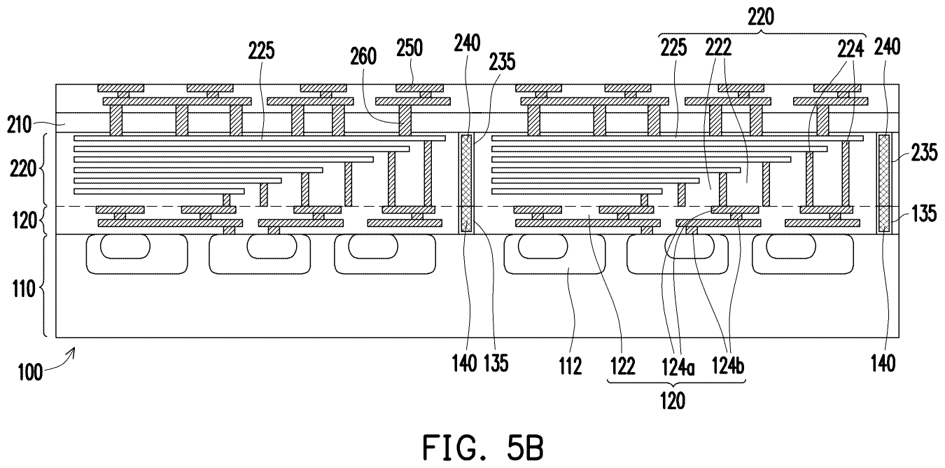

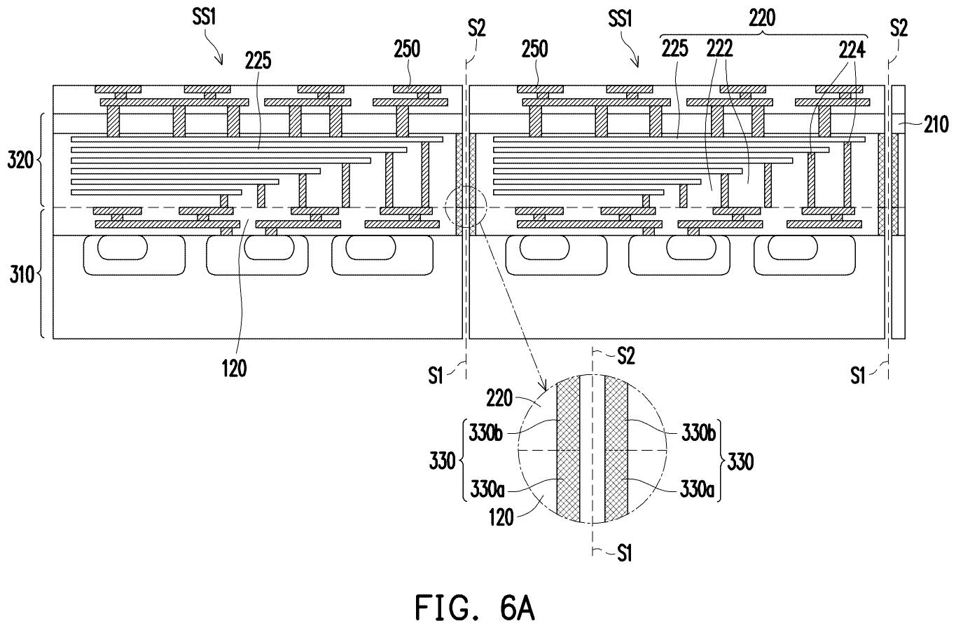

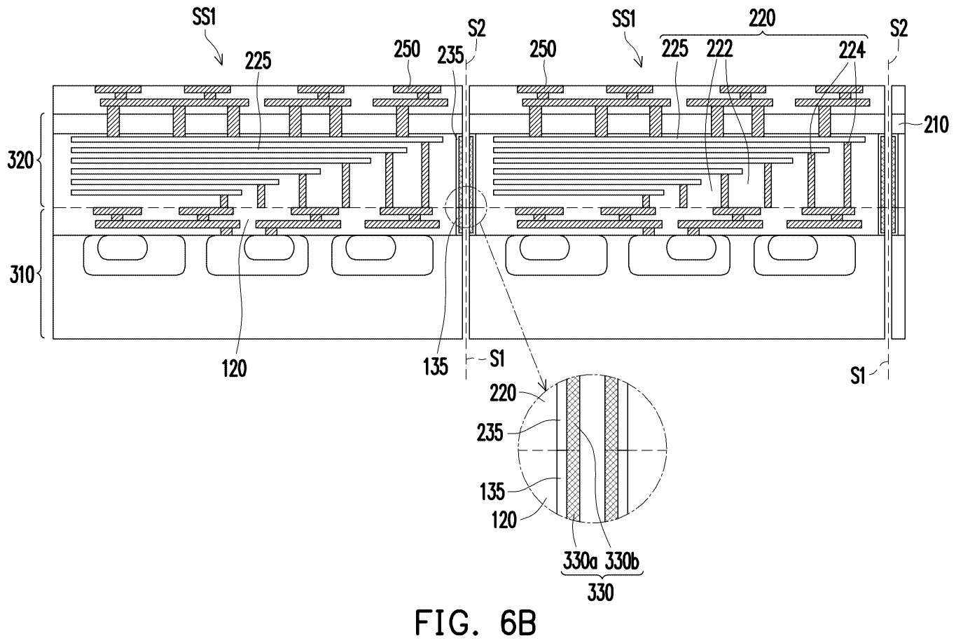

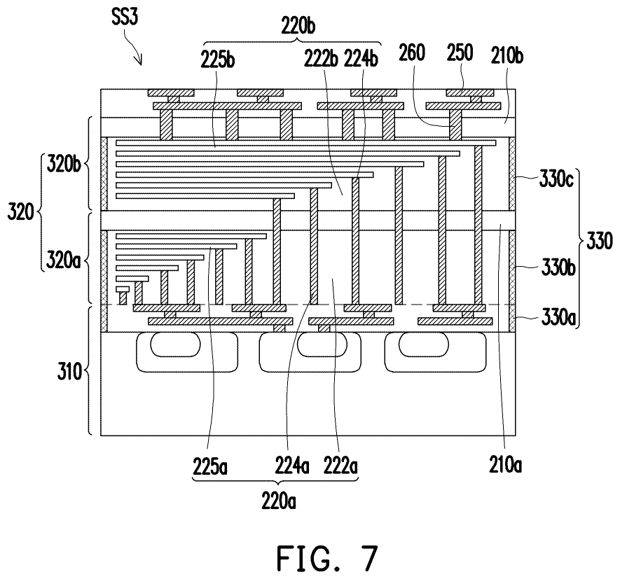

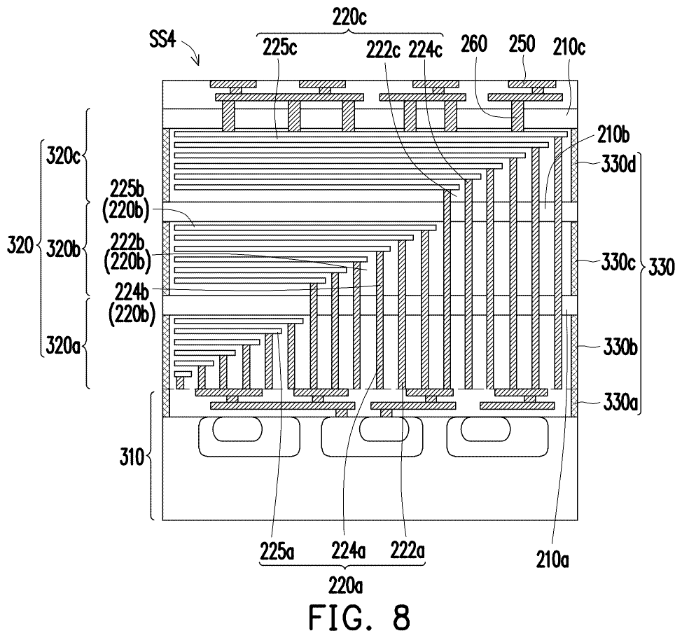

FIG. 7 is a schematic cross-sectional view of a semiconductor bonded structure SS3 according to the third embodiment of the disclosure.

Please refer to FIG. 7, the semiconductor bonded structure SS3 in the present embodiment includes the first semiconductor chip 310, a plurality of second semiconductor chips 320, a plurality of stress adjusting structures 330, and the conductive layer 250, wherein the plurality of second semiconductor chips 320 are stacked on the first semiconductor chip 310, the plurality of stress adjusting structures 330 are respectively embedded on the sidewalls of the plurality of second semiconductor chips 320, and the conductive layer 250 is disposed on the second semiconductor chips 320, and the conductive layer 250 is electrically connected to the second semiconductor chips 320. In the present embodiment, the second semiconductor chips 320 include a second semiconductor chip 320a and a second semiconductor chip 320b, wherein the second semiconductor chip 320a is disposed on the first semiconductor chip 310 and electrically connected to the first semiconductor chip 310, and the second semiconductor chip 320b is disposed on the second semiconductor chip 320a and electrically connected to the second semiconductor chip 320a. The second semiconductor chip 320b is located between the second semiconductor chip 320a and the first semiconductor chip 310. In addition, the second semiconductor chip 320b may be electrically connected to the first semiconductor chip 310 via the second semiconductor chip 320a.

The first semiconductor chip 310 in the present embodiment is the same as the first semiconductor chip 310 in the first embodiment, and is therefore not repeated herein.

In the present embodiment, the second semiconductor chip 320a includes a second semiconductor substrate 210a, a second interconnect structure 220a, and a plurality of memory device layers 225a, wherein the second interconnect structure 220a is disposed at the second semiconductor substrate 210a and electrically connected to the second semiconductor substrate 210a, the plurality of memory device layers 225a are embedded in a dielectric layer 222a of the second interconnect structure 220a, and the memory device layers 225a are electrically connected to the first semiconductor chip 310 via conductive vias 224a of the second interconnect structure 220a. Moreover, the second semiconductor chip 320b includes a second semiconductor substrate 210b, a second interconnect structure 220b, and a plurality of memory device layers 225b, wherein the second interconnect structure 220b is disposed at the second semiconductor substrate 210b and electrically connected to the second semiconductor substrate 210b, the plurality of memory device layers 225b are embedded in a dielectric layer 222b of the second interconnect structure 220b, and the memory device layers 225b are electrically connected to the conductive vias 224a via conductive vias 224b of the second interconnect structure 220b.

In the present embodiment, the stress adjusting structures 330 include the first stress adjusting region 330a, the second stress adjusting region 330b, and a third stress adjusting region 330c, wherein the first stress adjusting region 330a is embedded on the sidewall of the first semiconductor chip 310, the second stress adjusting region 330b is embedded on the sidewall of the second semiconductor chip 320a, and the third stress adjusting region 330c is embedded on the sidewall of the second semiconductor chip 320b. As shown in FIG. 7, the first stress adjusting region 330a and the second stress adjusting region 330b are in contact and bonded to each other, and the second stress adjusting region 330b and the third stress adjusting region 330c are separated from each other via the semiconductor substrate 210a of the second semiconductor chip 320a.

Here, the size, distribution pattern, and material selection of the first stress adjusting region 330a, the second stress adjusting region 330b, and the third stress adjusting region 330c are the same as those of the first stress adjusting region 330a and the second stress adjusting region 330b in the first embodiment, and are therefore not repeated herein.

In the present embodiment, the conductive layer 250 is disposed on the second semiconductor chip 320b, and the conductive layer 250 is electrically connected to the second semiconductor chip 320b. As shown in FIG. 7, the conductive layer 250 may be electrically connected to the memory device layers 225b via the TSVs 260 in the second semiconductor chip 320b.

### Fourth Embodiment

FIG. 8 is a schematic cross-sectional view of a semiconductor bonded structure according to the fourth embodiment of the disclosure.

Please refer to FIG. 7 and FIG. 8, a semiconductor bonded structure SS4 of the present embodiment is similar to the semiconductor bonded structure SS3 of the third embodiment except that the semiconductor bonded structure SS4 of the present embodiment further includes a second semiconductor chip 320d and a fourth stress adjusting region 330d, wherein the second semiconductor chip 320d is disposed between the second semiconductor chip 320c and the conductive layer 250, the fourth stress adjusting region 330d is disposed on the sidewall of the second semiconductor chip 320c, and the conductive layer 250 is electrically connected to the second semiconductor chip 320c via the second semiconductor chip 320d. In addition, the fourth stress adjusting region 330d and the third stress adjusting region 330c are separated from each other via the semiconductor substrate 210b of the second semiconductor chip 320b.

The second semiconductor chip 320c includes a second semiconductor substrate 210c, a second interconnect structure 220c, and a plurality of memory device layers 225c, wherein the second interconnect structure 220c is disposed at the second semiconductor substrate 210c and electrically connected to the second semiconductor substrate 210c, the plurality of memory device layers 225c are embedded in a dielectric layer 222c of the second interconnect structure 220c, and the memory device layers 225c are electrically connected to the second semiconductor chip 320b via conductive vias 224c of the second interconnect structure 220c.

### Fifth Embodiment

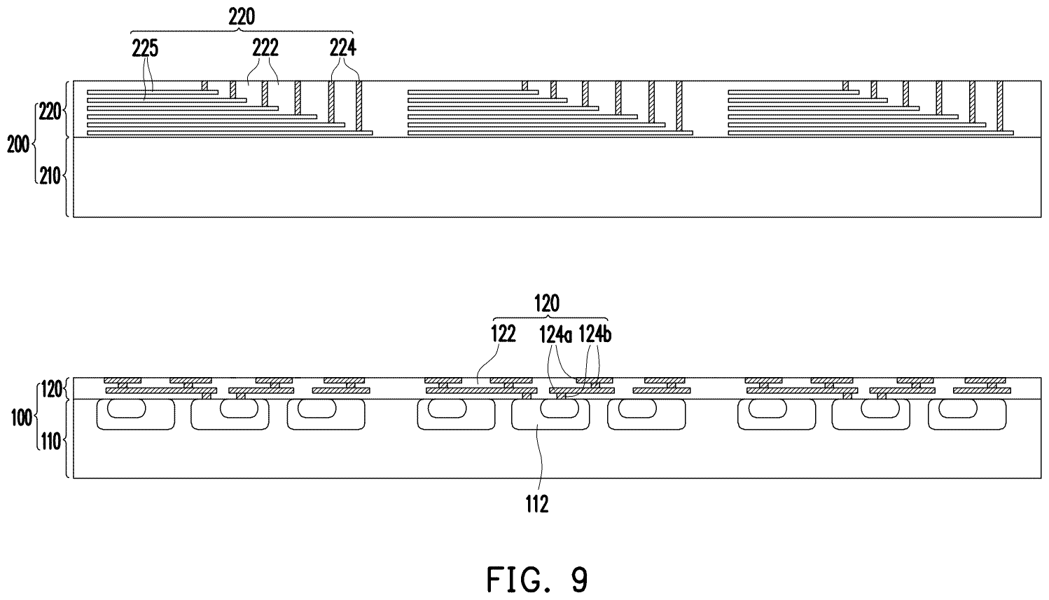

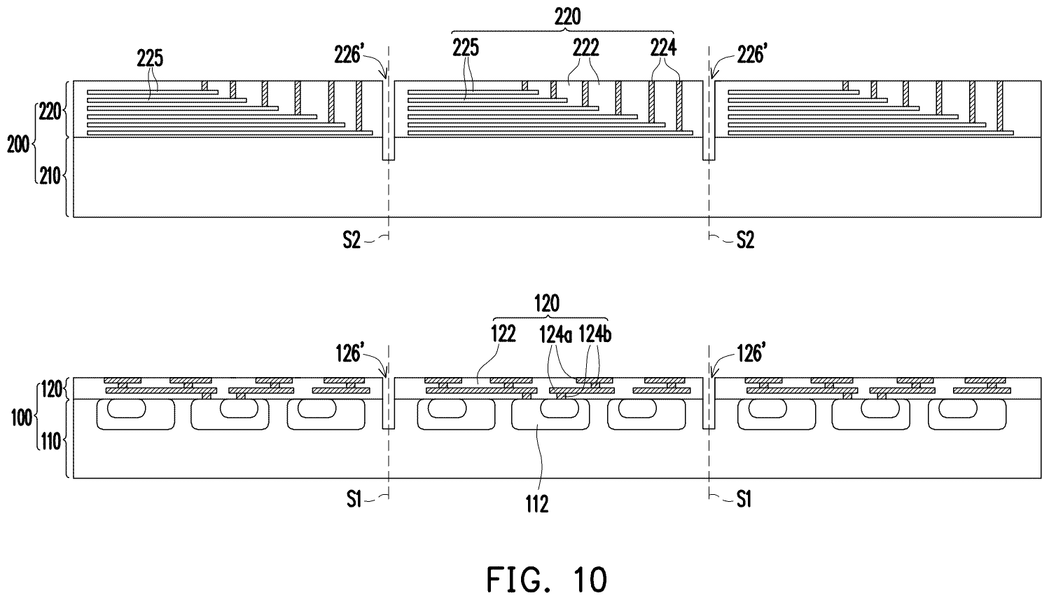

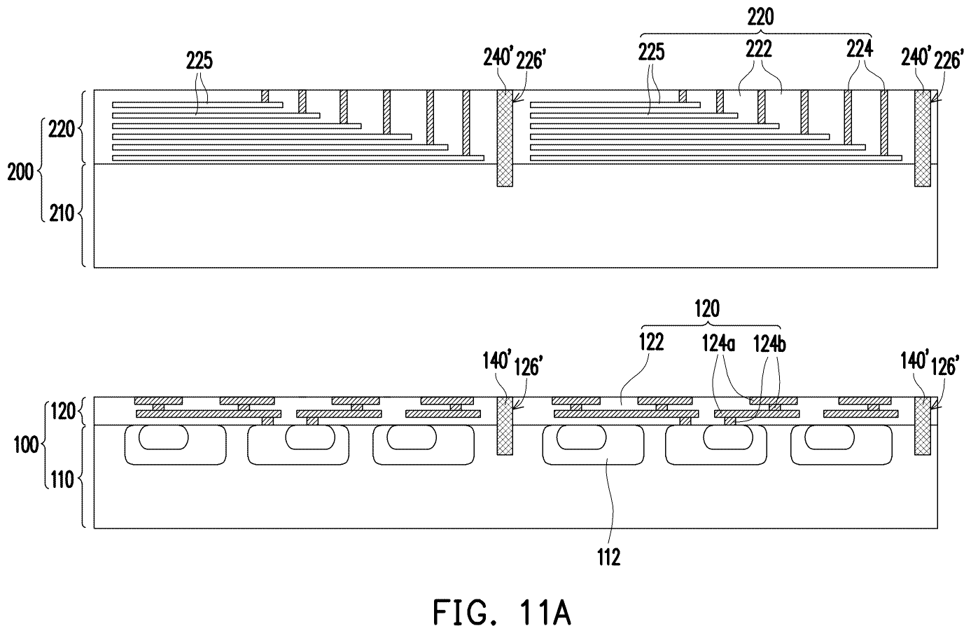

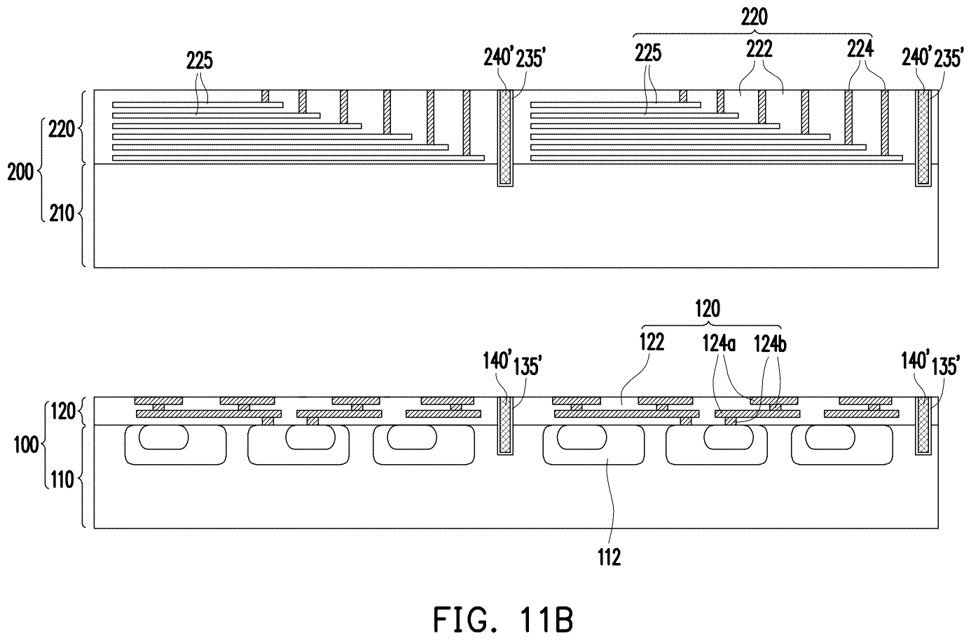

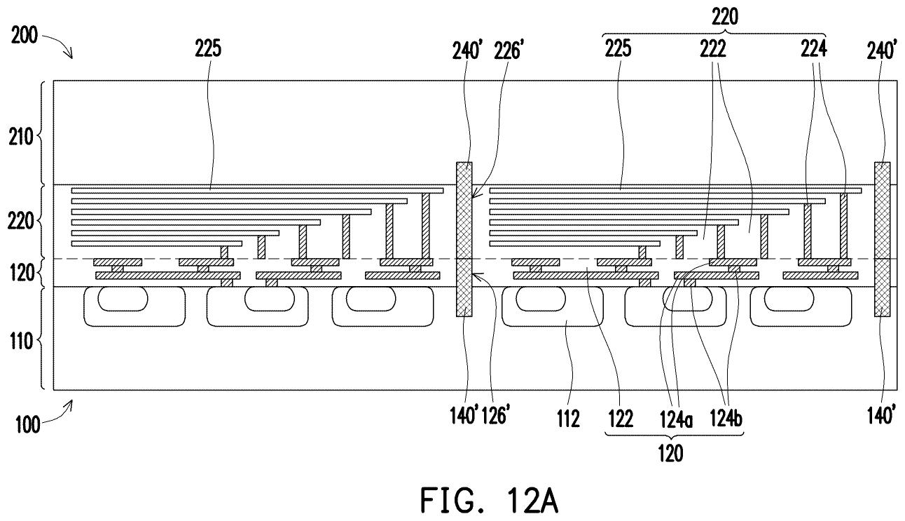

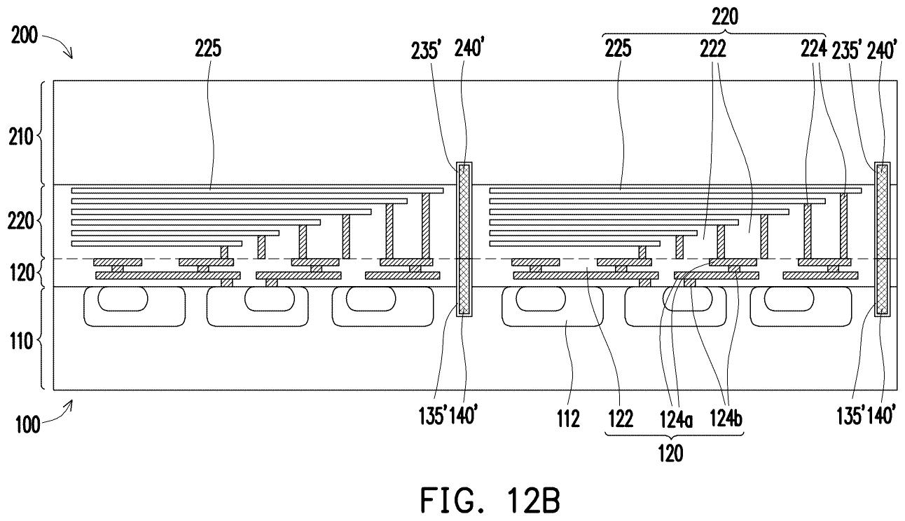

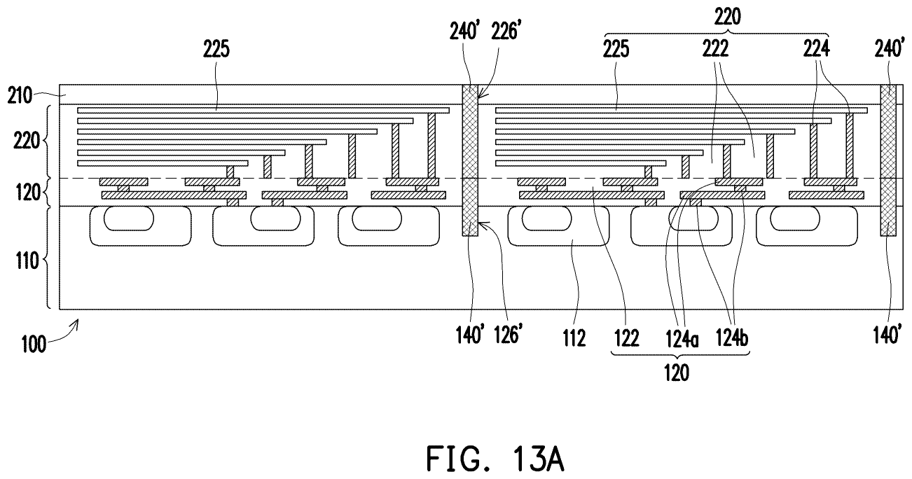

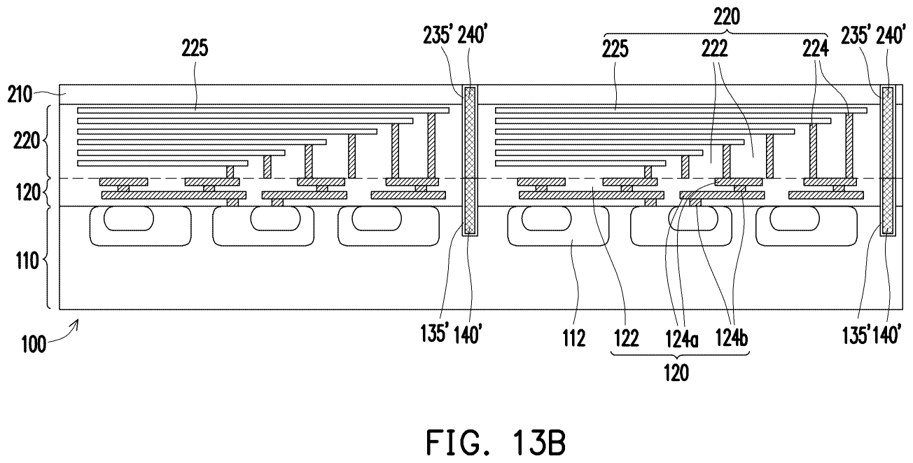

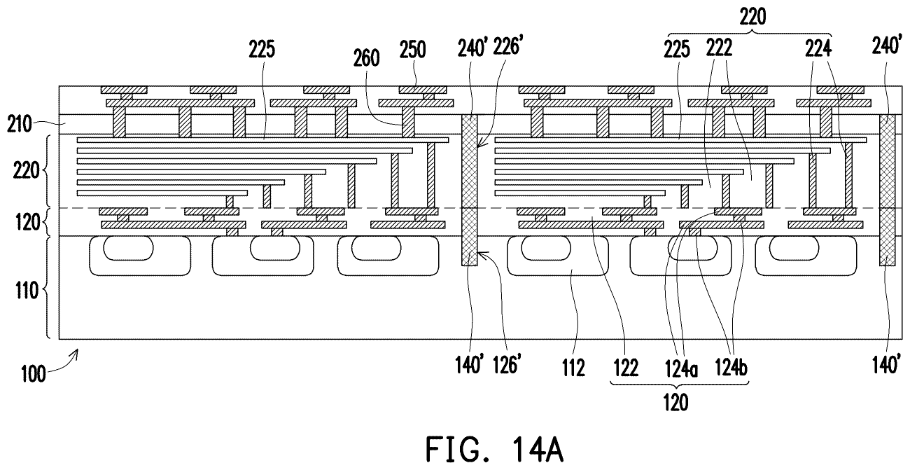

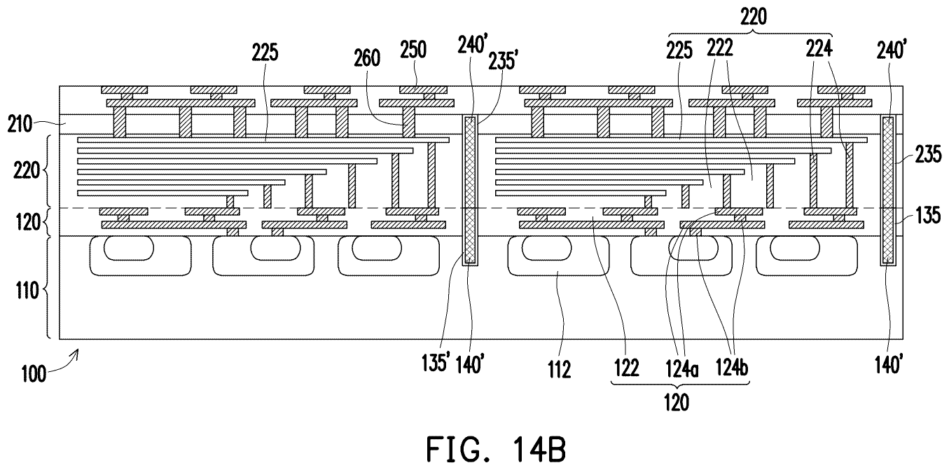

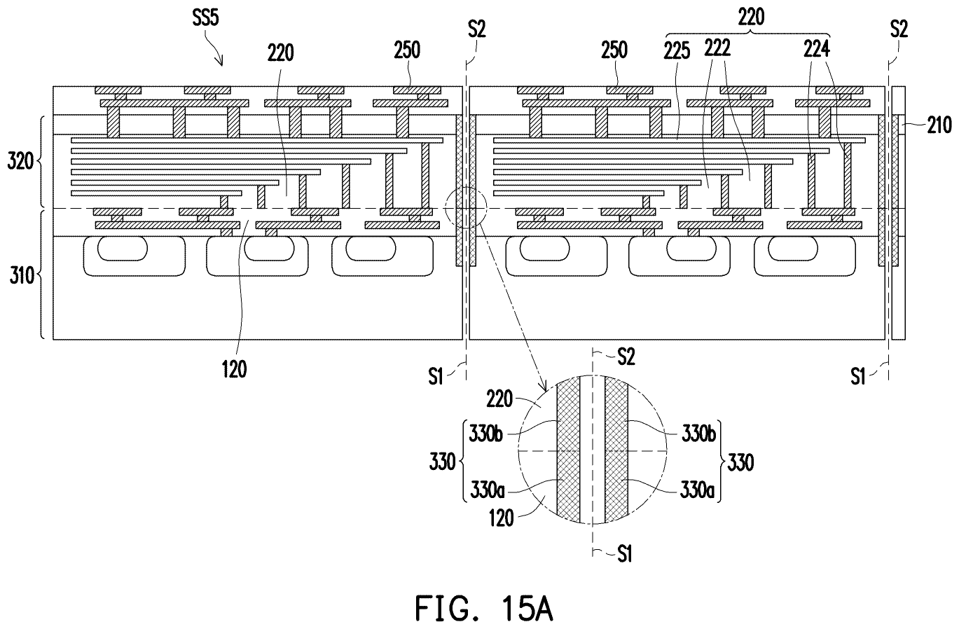

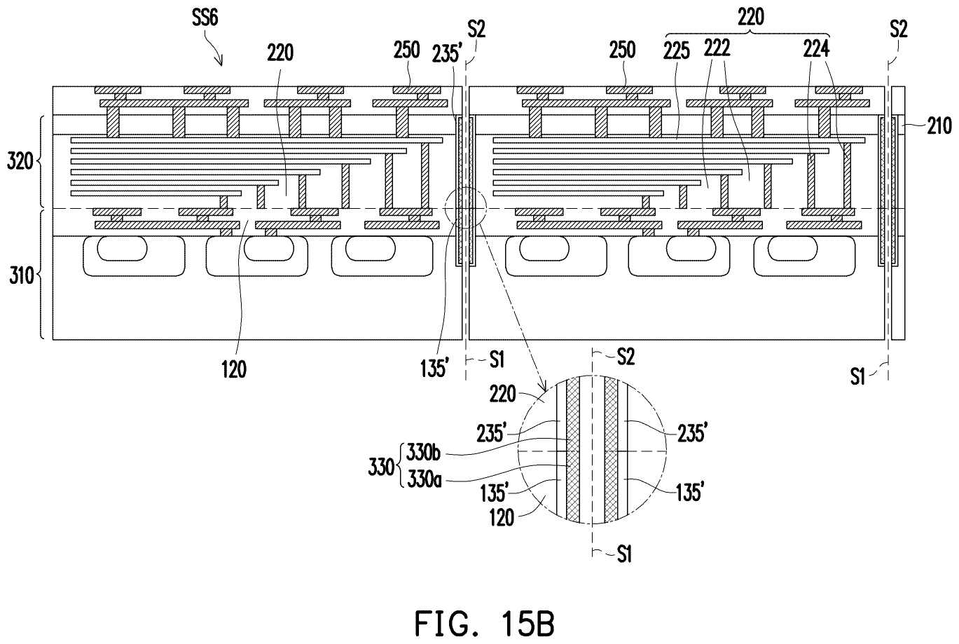

FIG. 9, FIG. 10, FIG. 11A, FIG. 12A, FIG. 13A, FIG. 14A, and FIG. 15A are schematic diagrams of a fabricating process of a semiconductor bonded structure SS5 according to the fifth embodiment of the disclosure.

Please refer to FIG. 9, FIG. 10, FIG. 11A, FIG. 12A, FIG. 13A, FIG. 14A, and FIG. 15A, the fabricating process of the semiconductor bonded structure SS5 of the present embodiment is similar to the fabricating process of the first embodiment except that in the present embodiment, a first stress adjusting opening 126′ (shown in FIG. 10) is extended into the first semiconductor substrate 110, and a second stress adjusting opening 226′ (shown in FIG. 10) is extended into the second semiconductor substrate 210.

As shown in FIG. 10, the height of the first stress adjusting opening 126′ is greater than the thickness of the first interconnect structure 120, and the height of the second stress adjusting opening 226′ is greater than the thickness of the second interconnect structure 220. In other words, the patterning process (e.g., etching process) used to pattern the first interconnect structure 120 removes a portion of the first semiconductor substrate 110, and the patterning process (e.g., etching process) used to pattern the second interconnect structure 220 removes a portion of the second semiconductor substrate 210. For example, the etching depth of the first semiconductor substrate 110 and the second semiconductor substrate 210 is between hundreds of nanometers and hundreds of micrometers.

As shown in 11A, a first stress adjusting structure 140′ formed in the first stress adjusting opening 126′ and a second stress adjusting structure 240′ formed in the second stress adjusting opening 226′ have a larger height. In other words, the bottom end of the first stress adjusting structure 140′ is embedded in the first semiconductor substrate 110, and the bottom end of the second stress adjusting structure 240′ is embedded in the second semiconductor substrate 210.

As shown in FIG. 12A, FIG. 13A and FIG. 14A, after the bonding process (illustrated in FIG. 12A) between the second semiconductor wafer 200 and the first semiconductor wafer 100 is performed and before the fabrication of the conductive layer 250 (illustrated in FIG. 14A) is performed, the second semiconductor substrate 210 may be thinned via a mechanical grinding process followed by a chemical mechanical polishing process. After the second semiconductor substrate 210 is thinned, an end (i.e., the bottom end above) of the second stress adjusting structure 240′ is exposed. Since the material of the stress adjusting structure 240′ is different from that of the second semiconductor substrate 210, the stress adjusting structure 240′ may act as a stop layer in the thinning process of the second semiconductor substrate 210. For example, by detecting the eddy current, the stress adjusting structure 240′ may act as a chemical mechanical polishing stop layer in the thinning process of the second semiconductor substrate 210. As shown in FIG. 15A, the stress adjusting structure 330 includes the first stress adjusting region 330a and the second stress adjusting region 330b, wherein the first stress adjusting region 330a is the remaining portion of the first stress adjusting structure 140′ after cutting, and the second stress adjusting region 330b is the remaining portion of the second stress adjusting structure 240′ after cutting. Moreover, the first stress adjusting region 330a is disposed on the sidewall of the first interconnect structure 120, and the second stress adjusting region 330b is disposed on the sidewall of the second interconnect structure 220. The height of the first stress adjusting structure 330a is less than the thickness of the first semiconductor chip 310 but greater than the thickness of the first interconnect structure 120 of the first semiconductor chip 310, and the height of the second stress adjusting structure 330b is substantially equal to the thickness of the second semiconductor chip 320.

### Sixth Embodiment

FIG. 9, FIG. 10, FIG. 11B, FIG. 12B, FIG. 13B, FIG. 14B, and FIG. 15B are

schematic diagrams of a fabricating process of a semiconductor bonded structure SS6 according to the sixth embodiment of the disclosure.

The fabricating process shown in FIG. 11B, FIG. 12B, FIG. 13B, FIG. 14B, and FIG. 15B is similar to the fabricating process shown in FIG. 11A, FIG. 12A, FIG. FIG. 13A, 14A, and FIG. 15A except that the fabricating process of the semiconductor bonded structure SS6 in FIG. 11B, FIG. 12B, FIG. 13B, FIG. 14B, and FIG. 15B further includes the forming of functional material layers 135′ and 235′. In other words, the semiconductor bonded structure SS6 in the present embodiment further includes the functional material layers 135′ and 235′ (as shown in FIG. 15B), wherein the first stress adjusting structure 140′ and the second stress adjusting structure 240′ are separated from the first interconnect structure 120 of the first semiconductor chip 310 and the second interconnect structure 220 of the second semiconductor chip 320 via the functional material layers 135′ and 235′. In some embodiments, the first stress adjusting region 330a and the second stress adjusting region 330b have a stress adjusting function, and the material of the functional material layers 135′ and 235′ may be a heat dissipation material having good heat dissipation properties, a water absorption material having good water absorption properties, or other functional materials.

### Seventh Embodiment

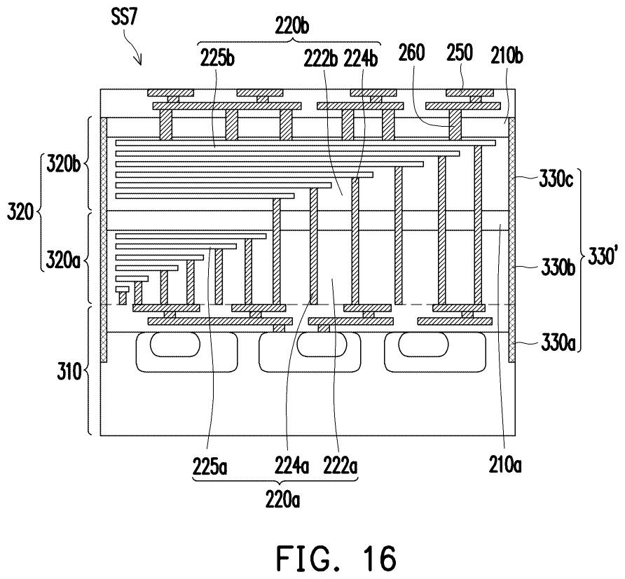

FIG. 16 is a schematic cross-sectional view of a semiconductor bonded structure SS7 according to the seventh embodiment of the disclosure.

Please refer to FIG. 16, the semiconductor bonded structure SS7 of the present embodiment is similar to the semiconductor bonded structure SS3 of the third embodiment except that a stress adjusting structure 330′ in the semiconductor bonded structure SS7 of the present embodiment.

In the present embodiment, the stress adjusting structure 330′ includes the first stress adjusting region 330a, the second stress adjusting region 330b, and the third stress adjusting region 330c, wherein the first stress adjusting region 330a is embedded on the sidewall of the first semiconductor chip 310, the second stress adjusting region 330b is embedded on the sidewall of the second semiconductor chip 320a, and the third stress adjusting region 330c is embedded on the sidewall of the second semiconductor chip 320b. As shown in FIG. 16, the first stress adjusting region 330a and the second stress adjusting region 330b are in contact and bonded to each other, and the second stress adjusting region 330b and the third stress adjusting region 330c are in contact and bonded to each other.

Here, the material selection of the first stress adjusting region 330a, the second stress adjusting region 330b, and the third stress adjusting region 330c is the same as that of the first stress adjusting region 330a and the second stress adjusting region 330b in the first embodiment, and are therefore not repeated herein.

### Eighth Embodiment

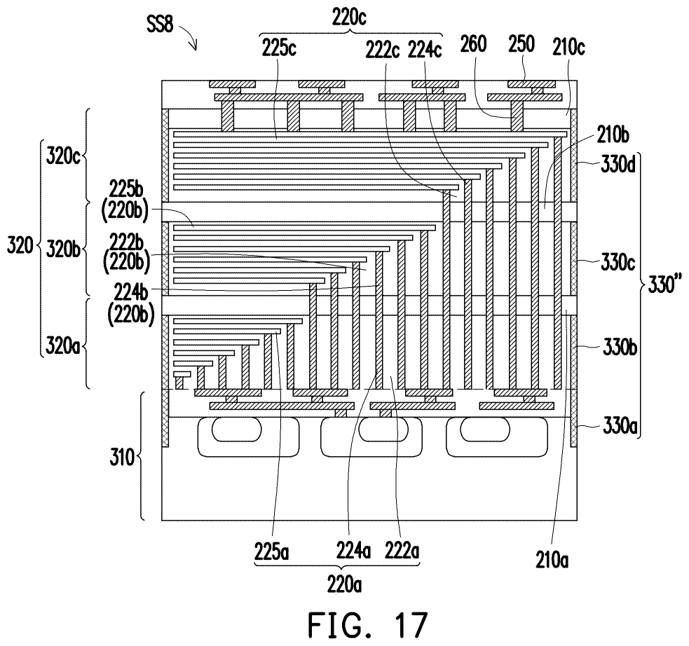

FIG. 17 is a schematic cross-sectional view of a semiconductor bonded structure SS8 according to the eighth embodiment of the disclosure.

Please refer to FIG. 16 and FIG. 17, the semiconductor bonded structure SS8 of the present embodiment is similar to the semiconductor bonded structure SS7 of the third embodiment except that a stress adjusting structure 330″ in the semiconductor bonded structure SS8 of the present embodiment.

In the present embodiment, the semiconductor bonded structure SS8 further includes a second semiconductor chip 320c, and the stress adjusting structure 330″ in the semiconductor bonded structure SS8 further includes a fourth stress adjusting region 330d, wherein the second semiconductor chip 320c is disposed between the second semiconductor chip 320b and the conductive layer 250, the fourth stress adjusting region 330d is disposed on the sidewall of the second semiconductor chip 320c, and the conductive layer 250 is electrically connected to the first semiconductor chip 310 via the second semiconductor chip 320c. In addition, the first stress adjusting region 330a and the second stress adjusting region 330b are in contact and bonded to each other, and the third stress adjusting region 330c is spaced apart from the overlying fourth stress adjusting region 330d and the underlying third stress adjusting region 330c are in contact and bonded to each other.

Ninth embodiment

Please refer to FIG. 18, FIG. 19, FIG. 20A, FIG. 21A, FIG. 22A, FIG. 23A, FIG. 24A, and FIG. 25A, the fabricating process of the present embodiment is used to fabricate the semiconductor bonded structure SS3 in the third embodiment.

Referring to FIG. 18, the first semiconductor wafer 100 is provided. Here, the details of the first semiconductor wafer 100 are described in the first embodiment, and are therefore not repeated herein.

As shown in FIG. 18, a second semiconductor wafer 200a and a second semiconductor wafer 200b are provided. In the present embodiment, the second semiconductor wafer 200a includes the second semiconductor substrate 210a, the second interconnect structure 220a, and the plurality of memory device layers 225a, wherein the second semiconductor substrate 210a may or may not have a semiconductor device, the second interconnect structure 220a is disposed on the second semiconductor substrate 210a, and the plurality of memory device layers 225a are stacked on the second semiconductor substrate 210a, and the plurality of memory device layers 225a are embedded in the second interconnect structure 220a. In some embodiments, the second semiconductor substrate 210a in the second semiconductor wafer 200a includes a Group IV semiconductor substrate (such as a silicon substrate), a Group III-V semiconductor substrate, or a substrate of other materials. The second interconnect structure 220a includes a plurality of dielectric layers 222a stacked on the second semiconductor substrate 210a and a plurality of layers of conductive vias 224a embedded in the dielectric layers 222a. In the present embodiment, the dielectric layers 222a and the conductive vias 224a in the second interconnect structure 220a are fabricated by back end of line (BEOL) processes. For example, the material of the dielectric layers 222a in the second interconnect structure 220a includes SiO₂, SiON, SiN, SiC, SiCN, a polymer material, or other insulating materials, and the material of the conductive vias 224a includes polysilicon, copper, gold, silver, cobalt, or other metals. In some embodiments, each of the memory device layers 225a is electrically connected to the bottom end of at least one of the conductive vias 224a respectively, and the top ends of the conductive vias 224a are exposed on the upper surface of the second interconnect structure 220a. As shown in FIG. 18, a portion of the conductive vias 224a is not electrically connected to the memory device layers 225a, but directly penetrate the second interconnect structure 220a and extended downward into the second semiconductor substrate 210a.

In some embodiments, the memory device layers 225a include a plurality of 3D NAND memory device layers, and the memory device layers 225a may include at least 300 layers of silicon oxide-silicon nitride-silicon oxide (ONO) stacks. In other possible embodiments, the memory device layers 225a include a plurality of 3D NAND memory device layers, and the memory device layers 225a may include at least 1000 layers of silicon oxide-silicon nitride-silicon oxide (ONO) stacks.

In the present embodiment, the second semiconductor wafer 200b includes the second semiconductor substrate 210b, the second interconnect structure 220b, and the plurality of memory device layers 225b, wherein the second semiconductor substrate 210b may or may not have a semiconductor device, the second interconnect structure 220b is disposed on the second semiconductor substrate 210b, and the plurality of memory device layers 225b are stacked on the second semiconductor substrate 210b, and the plurality of memory device layers 225b are embedded in the second interconnect structure 220b. In some embodiments, the second semiconductor substrate 210b in the second semiconductor wafer 200b includes a Group IV semiconductor substrate (such as a silicon substrate), a Group III-V semiconductor substrate, or a substrate of other materials. The second interconnect structure 220b includes a plurality of dielectric layers 222b stacked on the second semiconductor substrate 210b and a plurality of layers of conductive vias 224b embedded in the dielectric layers 222b. In the present embodiment, the dielectric layers 222b and the conductive vias 224b in the second interconnect structure 220b are fabricated by back end of line (BEOL) processes. For example, the material of the dielectric layers 222b in the second interconnect structure 220b includes SiO₂, SiON, SiN, SiC, SiCN, a polymer material, or other insulating materials, and the material of the conductive vias 224b includes polysilicon, copper, gold, silver, cobalt, or other metals. In some embodiments, each of the memory device layers 225b is electrically connected to the bottom end of at least one of the conductive vias 224b respectively, and the top ends of the conductive vias 224b are exposed on the upper surface of the second interconnect structure 220b.

In some embodiments, the memory device layers 225b include a plurality of 3D NAND memory device layers, and the memory device layers 225b may include at least 300 layers of silicon oxide-silicon nitride-silicon oxide (ONO) stacks. In other possible embodiments, the memory device layers 225b include a plurality of 3D NAND memory device layers, and the memory device layers 225b may include at least 1000 layers of silicon oxide-silicon nitride-silicon oxide (ONO) stacks.

Referring to FIG. 19 and FIG. 20A, in order to relieve the stress of the first semiconductor wafer 100, the second semiconductor wafer 200a, and/or the second semiconductor wafer 200b so as to reduce the degree of warpage of the first semiconductor wafer 100, the second semiconductor wafer 200a, and/or the second semiconductor wafer 200b, a patterning process (for example, an etching process) may be performed on at least one of the first semiconductor wafer 100, the second semiconductor wafer 200a, and the second semiconductor wafer 200b, and a stress adjusting structure is formed in at least one of the first semiconductor wafer 100, the second semiconductor wafer 200a, and the second semiconductor wafer 200b. In the present embodiment, a patterning process may be performed on the first semiconductor wafer 100, the second semiconductor wafer 200a, and the second semiconductor wafer 200b respectively, to form the first stress adjusting structure 140, a second stress adjusting structure 240a, and a second stress adjusting structure 240b in the first semiconductor wafer 100, the second semiconductor wafer 200a, and the second semiconductor wafer 200b respectively. It should be noted that the invention does not limit the forming sequence of the first stress adjusting structure 140, the second stress adjusting structure 240a, and the second stress adjusting structure 240b.

As shown in FIG. 19, a patterning process is performed on the first interconnect structure 120 of the first semiconductor wafer 100 to form the first stress adjusting openings 126 distributed in the first interconnect structure 120 along the first scribe line S1 of the first semiconductor wafer 100. A patterning process is performed on the second interconnect structure 220a of the second semiconductor wafer 200a to form second stress adjusting openings 226a distributed in the second interconnect structure 220a along the second scribe line S2 of the second semiconductor wafer 200a. A patterning process is performed on the second interconnect structure 220b of the second semiconductor wafer 200b to form second stress adjusting openings 226b distributed in the second interconnect structure 220b along a second scribe line S3 of the second semiconductor wafer 200b. In the present embodiment, the height of the first stress adjusting openings 126 is substantially equal to the thickness of the first interconnect structure 120, the height of the second stress adjusting openings 226a is substantially equal to the thickness of the second interconnect structure 220a, and the height of the second stress adjusting openings 226b is substantially equal to the thickness of the second interconnect structure 220b. Moreover, a partial area of the first semiconductor substrate 110 is exposed by the first stress adjusting openings 126, a partial region of the second semiconductor substrate 210a is exposed by the second stress adjusting openings 226a, and a partial area of the second semiconductor substrate 210b is exposed by the second stress adjusting openings 226b. After the first stress adjusting openings 126, the second stress adjusting openings 226a, and the second stress adjusting openings 226b are formed, since the stress of the first semiconductor wafer 100, the second semiconductor wafer 200a, and the second semiconductor wafer 200b is released by the first stress adjusting openings 126, the second stress adjusting openings 226a, and the second stress adjusting openings 226b, the warping of the first semiconductor wafer 100, the second semiconductor wafer 200a, and the second semiconductor wafer 200b may be alleviated to a certain extent.

As shown in FIG. 19 and FIG. 20A, a stress adjusting material is filled in the first stress adjusting openings 126 and the second stress adjusting openings 226, so as to respectively form the first stress adjusting structure 140, the second stress adjusting structure 240a, and the second stress adjusting structure 240b in the first stress adjusting openings 126, the second stress adjusting opening 226a, and the second stress adjusting openings 226b. In the present embodiment, by forming a stress adjusting material on the first interconnect structure 120 and in the first stress adjusting openings 126, then removing the stress adjusting material outside the first stress adjusting openings 126 by a planarization process (for example, a chemical mechanical polishing process, a mechanical grinding process, or a combination of the above processes), the first stress adjusting structure 140 may be formed. Moreover, by forming a stress adjusting material on the second interconnect structures 220a and 220b and in the second stress adjusting openings 226a and 226b, then removing the stress adjusting material outside the second stress adjusting openings 226a and 226b by a planarization process (for example, a chemical mechanical polishing process, a mechanical grinding process, or a combination of the above processes), the second stress adjusting structures 240a and 240b may be formed. In the present embodiment, the height of the first stress adjusting structure 140 is substantially equal to the thickness of the first interconnect structure 120, the height of the second stress adjusting structure 240a is substantially equal to the thickness of the second interconnect structure 220a, and the height of the second stress adjusting structure 240b is substantially equal to the thickness of the second interconnect structure 220b.

In some embodiments, the material of the first stress adjusting structure 140 and the second stress adjusting structures 240a and 240b includes a polymer material, such as polyimide (PI), epoxy resin, benzocyclobutene (BCB), SU-8, or other suitable stress buffering materials. The material of the first stress adjusting structure 140 may be the same as or different from the material of the second stress adjusting structures 240a and 240b. In other embodiments, the material of the first stress adjusting structure 140 and the second stress adjusting structures 240a and 240b includes an inorganic material, such as carbon, silicon, SiCN, silicon carbide (SiC), silicon oxide (SiOₓ), borophosphosilicate glass (BPSG), phosphosilicate glass (PSG), borosilicate glass (BSG), inorganic 2D material, etc. In other possible embodiments, the material of the first stress adjusting structure 140 and the second stress adjusting structures 240a and 240b includes a metal material, such as tungsten (W), copper (Cu), aluminum (Al), silver (Ag), gold (Au), metal 2D material, etc.

Based on the above, in addition to the function of stress adjustment, the first stress adjusting structure 140 and the second stress adjusting structures 240a and 240b may also have good heat dissipation properties, water absorption properties, or other functions.

Referring to FIG. 21A, the second semiconductor wafer 200a is turned over, and the second semiconductor wafer 200a is aligned with the first semiconductor wafer 100. After the second semiconductor wafer 200a and the first semiconductor wafer 100 are aligned, the second stress adjusting structure 240a in the second interconnect structure 220a is aligned with the first stress adjusting structure 140 in the first interconnect structure 120, and the conductive vias 224a in the second interconnect structure 220a are aligned with the interconnect wirings 124a in the first interconnect structure 120. After the alignment of the second semiconductor wafer 200a and the first semiconductor wafer 100 is completed, next, a bonding process between the second semiconductor wafer 200a and the first semiconductor wafer 100 is performed, such as a hybrid bonding process, a micro-bump bonding process, etc., so that the patterned first interconnect structure 120 and the patterned second interconnect structure 220a are bonded to each other. While the first interconnect structure 120 and the second interconnect structure 220a are bonded to each other, the second stress adjusting structure 240a is bonded to the first stress adjusting structure 140. Since the first stress adjusting structure 140 and the second stress adjusting structure 240a may reduce the warping of the second semiconductor wafer 200a and the first semiconductor wafer 100, the bonding yield between the second semiconductor wafer 200a and the first semiconductor wafer 100 may be improved.

Please refer to FIG. 21A and FIG. 22A, after the bonding process between the second semiconductor wafer 200a and the first semiconductor wafer 100 is performed, the second semiconductor substrate 210a may be thinned by a mechanical grinding process followed by a chemical mechanical polishing process first to expose a portion of the conductive vias 224a. In some embodiments, since the material of the conductive vias 224b is different from the material (e.g., silicon) of the dielectric layers 222b in the second interconnect structure 220b, the conductive vias 224a may functions as a stopping layer when performing the above-mentioned chemical mechanical polishing process of the second semiconductor substrate 210a.

Referring to FIG. 22A and FIG. 23A, the second semiconductor wafer 200b is turned over, and the second semiconductor wafer 200b is aligned with the second semiconductor wafer 200a. After the second semiconductor wafer 200b and the second semiconductor wafer 200a are aligned, the second stress adjusting structure 240b in the second interconnect structure 220b is aligned with the second stress adjusting structure 240a in the second interconnect structure 220a, and the conductive vias 224b in the second interconnect structure 220b are aligned with the conductive vias 224a in the second interconnect structure 220a. After the alignment of the second semiconductor wafer 200b and the second semiconductor wafer 200a is completed, a bonding process between the second semiconductor wafer 200b and the second semiconductor wafer 200a is performed, such as a hybrid bonding process, a micro-bump bonding process, etc., so that the patterned second interconnect structure 220a and the patterned second interconnect structure 220b are bonded to each other. While the second interconnect structure 220a and the second interconnect structure 220b are bonded to each other, the second stress adjusting structure 240a is bonded to the second stress adjusting structure 240b. Since the first stress adjusting structure 140, the second stress adjusting structure 240a, and the second stress adjusting structure 240b may reduce the warping of the first semiconductor wafer 100, the second semiconductor wafer 200a, and the second semiconductor wafer 200b, the bonding yield between the second semiconductor wafer 200a and the first semiconductor wafer 200b may be improved.

Please refer to FIG. 23A and FIG. 24A, after the bonding process between the second semiconductor wafer 200a and the second semiconductor wafer 200b is performed, the conductive layer 250 electrically connected to the second semiconductor wafer 200b is formed on the second semiconductor substrate 210b. In some embodiments, before the conductive layer 250 is fabricated, the second semiconductor substrate 210b may be thinned first by a mechanical grinding process followed by a chemical mechanical polishing process, and the plurality of conductive through vias 260 electrically connected to the memory device layers 225b are formed in the second semiconductor substrate 210b, and then the conductive layer 250 is fabricated. In some embodiments, the conductive through vias 260 may be through silicon vias (TSVs). As shown in FIG. 24A, the conductive layer 250 and the second interconnect structure 220b are respectively located at two opposite sides of the second semiconductor substrate 210b, and the conductive layer 250b is electrically connected to the memory device layers 225b via the TSVs 260.

Please refer to FIG. 24A and FIG. 25A, the first semiconductor wafer 100, the second semiconductor wafer 200a, the second semiconductor wafer 200b, the first stress adjusting structure 140, the second stress adjusting structure 240a, the second stress adjusting structure 240b, and the conductive layer 250 are cut along the first scribe line S1, the second scribe line S2, and the third scribe line S3 to form a plurality of singulated semiconductor bonded structures SS3.

### Tenth Embodiment

FIG. 18, FIG. 19, FIG. 20B, FIG. 21B, FIG. 22B, FIG. 23B, FIG. 24B, and FIG. 25B are schematic diagrams of a fabricating process of a semiconductor bonded structure according to the tenth embodiment of the disclosure.

The fabricating process shown in FIG. 20B, FIG. 21B, FIG. 22B, FIG. 23B, and FIG. 25B is similar to the fabricating process shown in FIG. 20A, FIG. 21A, FIG. 22A, FIG. 23A, FIG. 24A, and FIG. 25A except that the fabricating process in FIG. 20B, FIG. 21B, FIG. 22B, FIG. 23B, FIG. 24B, and FIG. 25B further includes the forming of functional material layers 135, 235a, and 235b. In addition to the above difference, a semiconductor bonded structure SS9 in the present embodiment further includes the functional material layers 135, 235a, and 235b (as shown in FIG. 6B), wherein the first stress adjusting region 330a, the second stress adjusting region 330b, and the third stress adjusting region 330c are separated from the first semiconductor chip 310 and the second semiconductor chip 320 via the functional material layers 135, 235a, and 235b. In some embodiments, the first stress adjusting region 330a, the second stress adjusting region 330b, and the third stress adjusting region 330c have a stress adjusting function, and the material of the functional material layers 135, 235a, and 235b may be a heat dissipation material having good heat dissipation properties, a water absorption material having good water absorption properties, or other functional materials.

### Eleventh Embodiment

FIG. 26 to FIG. 28 are schematic cross-sectional views of a fabricating process of a semiconductor bonded structure according to the eleventh embodiment of the disclosure.

Referring to FIG. 26, the first semiconductor wafer 100 and the second semiconductor wafer 200 are provided. Here, the details of the first semiconductor wafer 100 and the second semiconductor wafer 200 are described in the first embodiment, and are therefore not repeated herein.

In order to relieve the stress of the first semiconductor wafer 100 and/or the second semiconductor wafer 200 so as to reduce the degree of warpage of the first semiconductor wafer 100 and/or the second semiconductor wafer 200, a patterning process (for example, an etching process) may be performed on at least one of the first semiconductor wafer 100 and the second semiconductor wafer 200, and a stress adjusting opening is formed in at least one of the first semiconductor wafer 100 and the second semiconductor wafer 200. In the present embodiment, a patterning process may be performed on the second semiconductor wafer 200 to form the second stress adjusting openings 226 in the second semiconductor wafer 200.

As shown in FIG. 26, a patterning process is performed on the second interconnect structure 220 of the second semiconductor wafer 200 to form the second stress adjusting openings 226 distributed in the second interconnect structure 220 along the second scribe line S2 of the second semiconductor wafer 200. In the present embodiment, the height of the second stress adjusting openings 226 is less than the thickness of the second interconnect structure 220. Therefore, the second semiconductor substrate 210 is not exposed by the second stress adjusting openings 226.

After the second stress adjusting openings 226 are formed, since the stress of the second semiconductor wafer 200 is released by the second stress adjusting openings 226, the warpage of the second semiconductor wafer 200 having the plurality of memory device layers 225 may be improved to a certain extent.

It should be noted that in the present embodiment, no stress adjusting material and/or other functional materials are filled into the second stress adjusting openings 226.

Please refer to FIG. 27 to FIG. 28, the wafer bonding process (as shown in FIG. 27) and the cutting process (as shown in FIG. 28) in the present embodiment are similar to the wafer bonding process (as shown in FIG. 5A) and the cutting process (as shown in FIG. 6A) in the first embodiment. 6A), and are therefore not repeated herein.

As shown in FIG. 28, after the cutting process is completed, the fabrication of singulated semiconductor bonded structures SS10 is completed, wherein each of the plurality of singulated semiconductor bonded structures SS10 has a recess 226R capable of adjusting stress on the sidewall thereof respectively. In some embodiments, the recesses 226R capable of adjusting stress include annular recesses distributed on the sidewall of the second semiconductor chip 200. In some other embodiments, the recesses 226R capable of adjusting stress include a plurality of recesses distributed on the sidewall of the second semiconductor chip 200, and the recesses are separated from each other.

### Twelfth Embodiment

FIG. 29 to FIG. 33 are schematic cross-sectional views of a fabricating process of a semiconductor bonded structure according to the twelfth embodiment of the disclosure.

Referring to FIG. 29, the second semiconductor substrate 210 is provided, and a plurality of recesses 212 capable of adjusting stress are formed on the surface of the second semiconductor substrate 210. In some embodiments, the second semiconductor substrate 210 includes a Group IV semiconductor substrate (such as a silicon substrate), a Group III-V semiconductor substrate, or a substrate of other materials. The recesses 212 capable of adjusting stress may be formed by a photolithographic etching process. As shown in FIG. 29, the depth of the recesses 212 capable of adjusting stress may be less than the thickness of the second semiconductor substrate 210.

Referring to FIG. 30, a stress adjusting material is filled into the recesses 212 capable of adjusting stress to form a stress adjusting structure or a stress adjusting region 214. As shown in FIG. 30, the stress adjusting region is surrounded by the second semiconductor substrate 210 in the lateral direction. In the present embodiment, the stress adjusting region 214 may be formed by forming a stress adjusting material on the second semiconductor substrate 210 and in the recesses 212 capable of adjusting stress, and then removing the stress adjusting material outside the recesses 212 capable of adjusting stress by a planarization process (for example, a chemical mechanical polishing process, a mechanical grinding process, or a combination of the above processes). In some embodiments, the material of the stress adjusting region 214 includes a polymer material, such as polyimide (PI), epoxy resin, benzocyclobutene (BCB), SU-8, or other suitable stress buffering materials. The material of the stress adjusting region 214 is the same or different. In other embodiments, the material of the stress adjusting region 214 includes an inorganic material, such as carbon, silicon, SiCN, silicon carbide (SiC), silicon oxide (SiOₓ), borophosphosilicate glass (BPSG), phosphosilicate glass (PSG), borosilicate glass (BSG), inorganic 2D material, etc. In other possible embodiments, the material of the stress adjusting region 214 includes a metal material, such as tungsten (W), copper (Cu), aluminum (Al), silver (Ag), gold (Au), metal 2D material, etc. Based on the above, in addition to the function of stress adjustment, the stress adjusting region 214 may also have good heat dissipation properties, water absorption properties, or other functions.

In other possible embodiments, optionally at least one functional material layer may be formed between the stress adjusting region 214 and the second semiconductor substrate 210 (e.g., on the sidewall of the stress adjusting region 214 and/or on the bottom surface of the stress adjusting region 214), and the functional material may be a heat dissipation material having good heat dissipation properties, a water absorption material having good water absorption properties, or other functional materials.

Referring to FIG. 31, the second interconnect structure 220 and the plurality of memory device layers 225 are formed on the second semiconductor substrate 210 having the stress adjusting region 214, wherein the second interconnect structure 220 is disposed on the second semiconductor substrate 210, the plurality of memory device layers 225 are stacked on the second semiconductor substrate 210, and the plurality of memory device layers 225 are embedded in the second interconnect structure 220. In some embodiments, the second interconnect structure 220 includes the plurality of dielectric layers 222 stacked on the second semiconductor substrate 210 and the plurality of layers of conductive vias 224 embedded in the dielectric layers 222. In the present embodiment, the dielectric layers 222 and the conductive vias 224 in the second interconnect structure 220 are fabricated by back end of line (BEOL) processes. For example, the material of the dielectric layers 222 in the second interconnect structure 220 includes SiO₂, SiON, SiN, SiC, SiCN, a polymer material, or other insulating materials, and the material of the conductive vias 224 includes polysilicon, copper, gold, silver, cobalt, or other metals. In some embodiments, each of the memory device layers 225 is electrically connected to the bottom end of at least one of the conductive vias 224 respectively, and the top ends of the conductive vias 224 are exposed on the upper surface of the second interconnect structure 220.

In some embodiments, the memory device layers 225 include a plurality of 3D NAND memory device layers, and the memory device layers 225 may include at least 300 layers of silicon oxide-silicon nitride-silicon oxide (ONO) stacks. In other possible embodiments, the memory device layers 225 include a plurality of 3D NAND memory device layers, and the memory device layers 225 may include at least 1000 layers of silicon oxide-silicon nitride-silicon oxide (ONO) stacks.

Referring to FIG. 32, the first semiconductor wafer 100 is provided. Here, the first semiconductor wafer 100 is described in the first embodiment, and is therefore not repeated herein.

As shown in FIG. 32, the second semiconductor wafer 200 is turned over, and the second semiconductor wafer 200 is aligned with the first semiconductor wafer 100. After the second semiconductor wafer 200 is aligned with the first semiconductor wafer 100, the conductive vias 224 in the second interconnect structure 220 are aligned with the interconnect wirings 124a in the first interconnect structure 120. After the alignment of the second semiconductor wafer 200 and the first semiconductor wafer 100 is completed, a bonding process between the second semiconductor wafer 200 and the first semiconductor wafer 100 is performed, such as a hybrid bonding process, a micro-bump bonding process, etc., so that the patterned first interconnect structure 120 and the patterned second interconnect structure 220 are bonded to each other. Since the stress adjusting region 214 may reduce the warpage of the second semiconductor wafer 200, the bonding yield between the second semiconductor wafer 200 and the first semiconductor wafer 100 may be improved.

In some embodiments, before the second semiconductor wafer 200 and the first semiconductor wafer 100 are bonded, the second semiconductor substrate 210 may be thinned by a mechanical grinding process followed by a chemical mechanical polishing process until the stress adjusting region 214 is exposed. In some embodiments, since the material of the stress adjusting region 214 is different from the material (e.g., silicon) of the second semiconductor substrate 210, the stress adjusting region 214 may functions as a stopping layer when performing the above-mentioned chemical mechanical polishing process of the second semiconductor substrate 210.

In this case, the thickness of the stress adjusting region 214 is substantially equal to the thickness of the thinned second semiconductor substrate 210. In other possible embodiments, the thinning process of the second semiconductor substrate 210 may not need to expose the stress adjusting region 214. In this case, the thickness of the stress adjusting region 214 is substantially less than the thickness of the thinned second semiconductor substrate 210.

Please refer to FIG. 32 and FIG. 33, after the bonding process between the second semiconductor wafer 200 and the first semiconductor wafer 100 is performed, the conductive layer 250 electrically connected to the second semiconductor wafer 200 may be formed on the second semiconductor substrate 210 having the stress adjusting region 214. In some embodiments, before the fabrication of the conductive layer 250, the plurality of conductive through vias 260 electrically connected to the memory device layers 225 may be formed in the second semiconductor substrate 210. In some embodiments, the conductive vias 260 may be a plurality of through silicon vias (TSVs) penetrating through the stress adjusting region 214. As shown in FIG. 33, the conductive layer 250 and the second interconnect structure 220 are respectively located at two opposite sides of the second semiconductor substrate 210, and the conductive layer 250 is electrically connected to the memory device layers 225 via the TSVs 260.

The wafer bonding process (as shown in FIG. 32) and the cutting process (as shown in FIG. 33) in the present embodiment are similar to the wafer bonding process (as shown in FIG. 5A) and the cutting process (as shown in FIG. 6A) in the first embodiment. 6A), and are therefore not repeated herein.

Based on the above, the above embodiments of the present disclosure adopt different types of stress adjusting structures, stress adjusting openings, or recesses capable of adjusting stress to reduce the degree of warping of semiconductor wafers, thereby improving the bonding yield between the semiconductor wafers. Moreover, the above embodiments of the disclosure may improve the heat dissipation performance of the semiconductor bonded structure via the stress adjusting structures, the stress adjusting openings, or the recesses capable of adjusting stress, thereby improving the operation performance of the semiconductor bonded structure.

Although the disclosure has been described with reference to the above embodiments, it will be apparent to one of the ordinary skill in the art that modifications and variations to the described embodiments may be made without departing from the spirit and scope of the disclosure. Accordingly, the scope of the disclosure will be defined by the attached claims not by the above detailed descriptions.

What is claimed is:

1. A semiconductor bonded structure, comprising:
a first semiconductor chip;
at least one second semiconductor chip disposed on the first semiconductor chip and electrically connected to the first semiconductor chip;
a stress adjusting structure disposed in at least one of the first semiconductor chip and the at least one second semiconductor chip; and
a conductive layer disposed on and electrically connected to the at least one second semiconductor chip.

2. The semiconductor bonded structure of claim 1, wherein the stress adjusting structure comprises a first stress adjusting region disposed in the first semiconductor chip, and the first semiconductor chip comprises:
a first semiconductor substrate comprising a plurality of semiconductor devices; and
a first interconnect structure disposed on the first semiconductor substrate and electrically connected to the first semiconductor substrate, wherein a first stress adjusting region in the stress adjusting structure is disposed on a sidewall of the first interconnect structure.

3. The semiconductor bonded structure of claim 1, wherein the stress adjusting structure comprises a first stress adjusting region disposed in the first semiconductor chip, and the first semiconductor chip comprises:
a first semiconductor substrate comprising a plurality of semiconductor devices; and
a first interconnect structure disposed on the first semiconductor substrate and electrically connected to the first semiconductor substrate, wherein the first stress adjusting region is disposed on a sidewall of the first semiconductor substrate and a sidewall of the first interconnect structure.

4. The semiconductor bonded structure of claim 1, wherein the stress adjusting structure comprises a first stress adjusting region disposed in the first semiconductor chip, and the first stress adjusting region comprises an annular wall structure, and the annular wall structure surrounds the first semiconductor chip.

5. The semiconductor bonded structure of claim 1, wherein the stress adjusting structure comprises a first stress adjusting region disposed in the first semiconductor chip, and the first stress adjusting region comprises a plurality of columnar structures, the plurality of columnar structures are disposed around the first semiconductor chip, and the plurality of columnar structures are separated from each other.

6. The semiconductor bonded structure of claim 1, wherein the stress adjusting structure comprises a second stress adjusting region disposed in the second semiconductor chip, and the second semiconductor chip comprises:
a second semiconductor substrate; and
a second interconnect structure disposed on the second semiconductor substrate and electrically connected to the second semiconductor substrate, wherein the second interconnect structure comprises a plurality of memory device layers, and the second stress adjusting region is disposed on a sidewall of the second interconnect structure.

7. The semiconductor bonded structure of claim 1, wherein the stress adjusting structure comprises a second stress adjusting region disposed in the second semiconductor chip, and the second semiconductor chip comprises:
a second semiconductor substrate; and
a second interconnect structure disposed on the second semiconductor substrate and electrically connected to the second semiconductor substrate, wherein the second interconnect structure comprises a plurality of memory device layers, and the second stress adjusting region is disposed on a sidewall of the second semiconductor substrate and a sidewall of the second interconnect structure.

8. The semiconductor bonded structure of claim 1, wherein the stress adjusting structure comprises a second stress adjusting region disposed in the second semiconductor chip, and the second semiconductor chip comprises:
a second semiconductor substrate, wherein the second stress adjusting region is embedded in the second semiconductor substrate, and the second stress adjusting region is surrounded by the second semiconductor substrate; and
a second interconnect structure disposed on the second semiconductor substrate and electrically connected to the second semiconductor substrate, wherein the second interconnect structure comprises a plurality of memory device layers, and the second stress adjusting region is in contact with the second interconnect structure.

9. The semiconductor bonded structure of claim 8, wherein a height of the second stress adjusting region is less than or equal to a thickness of the second semiconductor substrate.

10. The semiconductor bonded structure of claim 1, wherein the stress adjusting structure comprises a second stress adjusting region disposed in the second semiconductor chip, and the second stress adjusting region comprises an annular wall structure, and the annular wall structure surrounds the second semiconductor chip.

11. The semiconductor bonded structure of claim 1, wherein the stress adjusting structure comprises a second stress adjusting region disposed in the second semiconductor chip, and the second stress adjusting region comprises a plurality of columnar structures, the plurality of columnar structures are disposed around the second semiconductor chip, and the plurality of columnar structures are separated from each other.

12. The semiconductor bonded structure of claim 1, wherein the stress adjusting structure comprises a second stress adjusting region disposed in the second semiconductor chip, and the second stress adjusting region comprises a plurality of recesses capable of adjusting stress, the plurality of recesses capable of adjusting stress are distributed on a sidewall of the second semiconductor chip, and the plurality of recesses capable of adjusting stress are separated from each other.

13. The semiconductor bonded structure of claim 1, wherein a height of the first stress adjusting region is less than a thickness of the first semiconductor chip, and a height of the second stress adjusting region is less than or equal to a thickness of the second semiconductor chip.

14. A fabricating method of a semiconductor bonded structure, comprising:
providing a first semiconductor wafer, and the first semiconductor wafer comprises a first semiconductor substrate and a first interconnect structure disposed on the first semiconductor substrate;
patterning the first interconnect structure of the first semiconductor wafer to form a first stress adjusting opening along a first scribe line of the first semiconductor wafer;
providing a second semiconductor wafer, and the second semiconductor wafer comprises a second semiconductor substrate and a second interconnect structure disposed on the second semiconductor substrate;
patterning the second interconnect structure of the second semiconductor wafer to form a second stress adjusting opening along a second scribe line of the second semiconductor wafer;
bonding the first interconnect structure and the second interconnect structure;
forming a conductive layer on the second semiconductor substrate after the first interconnect structure and the second interconnect structure are bonded; and
cutting the first semiconductor wafer, the second semiconductor wafer, and the conductive layer along the first scribe line and the second scribe line to form a plurality of singulated semiconductor bonded structures, wherein each of the plurality of singulated semiconductor bonded structures has a recess capable of adjusting stress on a sidewall thereof respectively.

15. The fabricating method of the semiconductor bonded structure of claim 14, further comprising:
filling a stress adjusting material in the first stress adjusting opening and the second stress adjusting opening before the first interconnect structure and the second interconnect structure are bonded.

16. The fabricating method of the semiconductor bonded structure of claim 15, wherein during the cutting of the first semiconductor wafer, the second semiconductor wafer, and the conductive layer along the first scribe line and the second scribe line, the stress adjusting material is cut to form a stress adjusting structure located in the recess capable of adjusting stress.

17. The fabricating method of the semiconductor bonded structure of claim 14, further comprising:
forming a conductive via in the second semiconductor substrate before the conductive layer is formed on the second semiconductor substrate, wherein the conductive layer is electrically connected to the second interconnect structure via the conductive via.

18. The fabricating method of the semiconductor bonded structure of claim 14, further comprising:
thinning the second semiconductor substrate before the conductive layer is formed on the second semiconductor substrate; and
forming a conductive via in the thinned second semiconductor substrate, wherein the conductive layer is electrically connected to the second interconnect structure via the conductive via.

19. A fabricating method of a semiconductor bonded structure, comprising:
providing a first semiconductor wafer, and the first semiconductor wafer comprises a first semiconductor substrate and a first interconnect structure disposed at the first semiconductor substrate;
providing a second semiconductor wafer, and the second semiconductor wafer comprises a second semiconductor substrate, a plurality of stress adjusting structures embedded in the second semiconductor substrate, and a second interconnect structure disposed on the second semiconductor substrate and the plurality of stress adjusting structures, wherein the second interconnect structure comprises a plurality of memory device layers disposed on the second semiconductor substrate; and
bonding the first semiconductor wafer and the second semiconductor wafer;
forming a conductive layer on the second semiconductor substrate and on the plurality of stress adjusting structures after the first semiconductor wafer and the second semiconductor wafer are bonded.

20. The fabricating method of the semiconductor bonded structure of claim 19, wherein a method of providing the second semiconductor wafer comprises:
forming a plurality of grooves separated from each other on a surface of the second semiconductor substrate;
forming the plurality of stress adjusting structures in the plurality of grooves;
thinning the second semiconductor substrate; and
forming the second interconnect structure on the second semiconductor substrate and the plurality of stress adjusting structures.
